(19) United States
(12) Patent Application Publication
(10) Pub. No.: US 2018/0120401 A1
(43) Pub. Date: May 3, 2018

(54) METHODS FOR OPTIMAL GRADIENT DESIGN AND FAST GENERIC WAVEFORM SWITCHING

(71) Applicants: HeartVista, Inc., Los Altos, CA (US); The Board of Trustees of the Leland Stanford Junior University, Palo Alto, CA (US)

(72) Inventors: Taehoon SHIN, Menlo Park, CA (US); Bob HU, Los Altos Hills, CA (US); William OVERALL, Los Altos, CA (US); Juan Santos, Los Altos, CA (US)

(21) Appl. No.: 15/833,514

(22) Filed: Dec. 6, 2017

Related U.S. Application Data
(63) Continuation-in-part of application No. 14/640,685, filed on Mar. 6, 2015.
Application No. 14/640,685 is a continuation of application No. PCT/US13/21077, filed on Jan. 10, 2013.
Application No. PCT/US13/21077 is a continuation-in-part of application No. 13/780,395, filed on Feb. 28, 2013.
(60) Provisional application No. 61/698,522, filed on Sep. 7, 2012.
(60) Provisional application No. 61/698,504, filed on Sep. 7, 2012.
(60) Provisional application No. 61/605,018, filed on Feb. 29, 2012.

(51) Int. Cl. G01R 33/56; G01R 33/385; G01R 33/48; G01R 33/561

(52) U.S. Cl. CPC G01R 33/5608; G01R 33/561; G01R 33/4822; G01R 33/3852

(57) ABSTRACT

This disclosure provides a computer-implemented method for sequencing magnetic resonance imaging waveforms using a multistage sequencing hardware. The method comprises creating, with the aid of a computer processor, an active memory region that includes waveforms and schedules being played, and creating one or more buffer memory regions that contain waveforms and schedules not currently being played. Next, the waveforms and schedules in the one or more buffer memory regions may be updated while waveforms may be played in the active memory region. Upon completion of the waveform playback in the active memory region, the active and buffer memory regions may be swapped so that the former buffer memory region becomes the active memory region, and the former active memory region becomes the buffer memory region. The method may be repeated as needed until the imaging process is completed or otherwise halted.

### CROSS-REFERENCE

This application is a continuation-in-part of U.S. patent application Ser. No. 14/640,685, filed Mar. 6, 2015, which is a continuation of PCT/US2013/021077, filed on Jan. 10, 2013, which claims the benefits of U.S. Provisional Application Nos. 61/698,522, filed Sep. 7, 2012, and 61/698,504, filed Sep. 7, 2012, which applications are entirely incorporated herein by reference; and this application is also a continuation-in-part of U.S. patent application Ser. No. 13/780,395, filed Feb. 28, 2013, which claims the benefit of U.S. Provisional Application No. 61/605,018, filed Feb. 29, 2012, which applications are entirely incorporated herein by reference.

### STATEMENT AS TO FEDERALLY SPONSORED RESEARCH

Aspects of the present disclosure may have been made with the support of the United States government under Contract number R44HL084769, R44HL092691, and 5R44HL084769 by the National Institutes of Health. The government may have certain rights in the invention(s) of the present disclosure.

### BACKGROUND

The present disclosure relates generally to medical devices and methods. Although specific reference is made to magnetic resonance imaging (MM), the methods and apparatus described herein can be used with many medical imaging and diagnostic procedures and apparatuses.

Magnetic resonance imaging (MRI) relies on the principles of nuclear magnetic resonance (NMR). In MM, an object to be imaged is placed in a uniform magnetic field (B₀), subjected to a limited-duration magnetic field (B₁) perpendicular to B₀, and then signals are detected as the “excited” nuclear spins in the object “relax” back to their equilibrium alignment with B₀ following the cessation of B₁. Through the application of additional magnetic fields (“gradients”) to the imaging process, detected signals can be spatially localized in up to three dimensions.

MRI of living subjects generally makes use of water protons found in tissues. In a typical imaging setup, a subject may then be first placed in a uniform magnetic field (B₀), where the individual magnetic moments of the water protons in the subject's various tissues align along the axis of B₀ and precess about it at the so-called Larmor frequency. The imaged subject may then be exposed to a limited-duration “excitation” magnetic field (B₁, generally created by application of a radio-frequency (RF) “pulse”) perpendicular to B₀ and at the Larmor frequency, where the net aligned magnetic moment (the sum of all individual proton moments aligned with B₀) at equilibrium, m₀, is temporarily rotated, or “tipped” toward the plane corresponding to B₁ (the “transverse” plane). This results in the formation of a net moment, mₜ, in the transverse plane. After cessation of B₁, a signal may be recorded from mₜ as it “relaxes” back to m₀. The local magnetic field environment of each tissue affects mₜ relaxation rates uniquely, resulting in tissue differentiation on images. Moreover, magnetic field gradients are typically employed in order to spatially localize the signals recorded from mₜ. The excitation/gradient application/signal readout process, a so-called “pulse sequence”, may be performed repetitively in order to achieve appropriate image contrast. The resulting set of received signals may then be processed with reconstruction techniques to produce images useful to the end-user.

Advances in the field of Magnetic Resonance Imaging (MRI), such as gradient hardware, high field systems, optimized receiver coil arrays, fast sequences and sophisticated reconstruction methods, provide the ability to perform rapid MRI imaging. In at least some instances, however, the capabilities of an MRI machine may be limited by memory capacity and processing speed. Improved methods and apparatuses for performing rapid MRI imaging, particularly in a memory and processing power limited MRI machine, are therefore desired.

Time-efficient production of time-optimal gradient waveforms that comply with safety and hardware gradient rate-of-change limitations is generally recognized as an important challenge for real-time MRI. While other methods may adequately calculate time-efficient gradient waveforms that conform to hardware and safety rate-of-change limitations, they may take many minutes to compute, and may render them unusable for real-time imaging. Thus, improved methods and apparatuses for providing more time-efficient gradient waveforms that conform to hardware and safety rate-of-change limitations in MRI machines are desired.

Contrast media, also referred to as contrast agents and/or contrast substances, have traditionally been used to assist medical professionals in obtaining visualizations of internal portions of the body of a subject (e.g., human). Some of the more ferrous contrast substances are receptive to MRI due to the their ability to respond to magnetism, while other contrast substances, due to their ability to absorb radiation, are receptive to x-ray technologies, such as computed axial topography (CAT) and other fluoroscopic devices. The suitability of a method of imaging (e.g., x-ray based imaging, magnetic-based imaging, etc.) is at least in part dependent upon the type of tissue being imaged. Consequently, the suitability of a particular contrast substance is a function of at least the ability of the contrast substance to respond to the type of imaging that is appropriate for the type of tissue being imaged. The varying levels of radiation absorption and/or magnetic response are what facilitate imaging of the interior of the body of a subject.

Iodine is the most common contrast substance used for the soft tissue fluoroscopic imaging of spinal areas, due to its heightened ability to absorb radiation. Gadolinium is a ferrous material that responds well to magnetic imaging.

Tissue damage can be shown or detected using magnetic resonance (MR) image data based on contrast agents such as those agents that attach to or are primarily retained in one of, but not both, healthy and unhealthy tissue, e.g., the contrast agent is taken up by, attaches to, or resides or stays in one more than in the other so that MR image data will visually identify the differences (using pixel intensity). The contrast agent can be a biocompatible agent, currently typically gadolinium, but may also include an antibody or derivative or component thereof that couples to an agent and selectively binds to an epitope present in one type of tissue but not the other (e.g., unhealthy tissue) so that the epitope is present in substantially amounts in one type but not the other. Alternatively, the epitope can be present in both types of tissue but is not susceptible to bind to one type by steric block effects.

A tissue characteristic map may use MR image data acquired in association with the uptake and retention of a contrast agent. Typically, a longer retention in tissue is associated with unhealthy tissue (such as infarct tissue, necrotic tissue, scarred tissue and the like) and is visually detectable by a difference in image intensity in the MR image data to show the difference in retention of one or more contrast agents. This is referred to as delayed enhancement (DE), delayed hyper-enhancement (DHE) or late gadolinium enhancement (LGE). As discussed above, in some embodiments, the system/circuit can employ interactive application of non-selective saturation to show the presence of a contrast agent in near real-time scanning. This option can help, for example, during image-guided catheter navigation to target tissue that borders scar regions. Thus, the DHE image data in a DHE tissue characterization map can be pre-acquired and/or may include near real time (RT) image data.

### SUMMARY

In an aspect, this disclosure provides a method that generates time-efficient linear magnetic field gradient waveforms that may produce magnetic field gradient pulses that come within 10% or better of the regulatory and/or hardware limit and may need only milliseconds to compute is provided. Moreover, the method may also be extended to design of specific k-space trajectories, non-linear magnetic field gradients, and new pulse sequence applications such as the optimization method of the disclosure, where the gradient area, moment, and start/end amplitudes may be the desired input parameters.

This disclosure provides systems and methods for graphically or programmatically creating pulse sequences based upon parameters relevant to the MRI pulse-sequence designer are provided. Many current magnetic resonance imaging (MRI) scanners require the pulse-sequence designer to independently determine and design the shapes of gradient waveforms that meet certain desired requirements, and only provide certain primitive structures such as trapezoids and ramps to help accomplish this design. Typically, an MRI pulse-sequence designer desires a certain gradient area and/or moment to be realized on one or more gradient axes, with given start and end amplitudes, rather than be interested in the specific shape of the waveform for most applications. Matching design tools to these user needs can greatly improve the ability to design new MRI acquisition strategies with a minimum of designer effort and time.

Real-time MRI may also require that sets of arbitrary waveforms and playback schedules be rapidly uploaded into a piece of dedicated magnetic resonance (MR) sequencing hardware that may be limited in processing power and/or available memory. Parameters of these waveforms such as their durations, amplitudes, data points, and number may all change arbitrarily and may not be known ahead of time.

This disclosure also provides a method for generating magnetic field gradients used in magnetic resonance imaging (MRI). With the aid of a computer processor, a set of gradient parameters is transformed from a physical gradient space into a transformed space (e.g., with at least one of a rotative transformation, a proportional transformation, a magnitude transformation, etc.). With the aid of a computer processor, a set of separable gradient waveforms that satisfy a set of gradient rate-of-change constraints in the transformed space is calculated. The set of gradient parameters may contain parameters that include a gradient start magnitude, gradient end magnitude, gradient amplitude, gradient first moment, and higher-order gradient moments. At least two of these parameters may typically be used. The set of rate-of-change constraints may comprise one or more of a physical hardware constraint and a regulatory safety constraint. The transforming and calculating steps are repeated until the gradient waveforms in the set of separable gradient waveforms are of substantially the same time length. This step of repetition may be a nonlinear solution method. With the aid of a computer processor, the resulting gradient set of waveforms of substantially the same time length is transformed back into the physical gradient space.

This disclosure also provides methods for rapidly and efficiently uploading arbitrary waveforms and playback schedules into a piece of sequencer hardware (e.g., MRI hardware) at any point, including during sequence execution, while minimizing playback time, system processing, and data storage requirements. When schedules are created in this way, preparation processing time can be reduced from many seconds to milliseconds or less. When preparation times cross the important threshold of requiring roughly less processing time than about the sequence repetition time (TR), which may be as short as a few milliseconds, sequences can be prepared just-in-time during sequence execution. This just-in-time sequence preparation enables true real-time manipulation of the imaging acquisition in arbitrary ways with little perceptible latency between action and reaction. Moreover, memory requirements for alternative schedules can be reduced by an order of magnitude through storing only the current and next iterations at any given time.

For example, a method for sequencing waveforms used in magnetic resonance imaging (MRI) may be provided. An active memory region and on or more buffer memory regions in a computer-readable medium are provided. The active memory region comprises one or more waveforms and schedules being played while the one or more buffer regions comprise one or more waveforms and schedules not currently being played. With the aid of a computer processor, the one or more waveforms and schedules not currently being played in the one or more buffer memory regions are updated while the one or more waveforms and schedules of the active memory region are being played. Upon the completion of the waveform playback in the active memory region, the active memory region and the buffer memory region are swapped with the aid of a computer processor. This swapping may occur without sequencer inactivity or delay. These steps are repeated until the imaging process is complete.

The waveforms of the active memory region and the one or more buffer regions may comprise at least one gradient waveform, RF channel waveform, shim waveform, field waveform, or acoustic waveform. The schedules of the active memory region and the one or more buffer regions may comprise pointers to at least one waveform region, duration, amplitude, or delay interval. The waveform playback may comprise a time interval per iteration which may vary from one iteration to another.

Updating the one or more waveforms and schedules not being played in the one or more buffer memory regions may comprise two or more steps. The one or more waveforms and schedules not being played are subdivided into one or more blocks that represent sequencing regions that are independently modifiable. Real-time changes are performed on individual blocks. Such real-time changes comprise one or more of scaling, rotation, enabling, and disabling.

This disclosure also provides a method for permitting real-time changes to waveforms used in magnetic resonance imaging (MRI). A time interval is subdivided into one or more blocks that represent sequencing regions that are independently modifiable. Real-time changes are performed on individual blocks. Such real-time changes comprise one or more of scaling, rotation, enabling, and disabling.

This disclosure also provides a method of generating a waveform used in imaging applications. A first combined constraint for an imaging device is determined by calculating, with the aid of a computer processor, an intersection between a first multidimensional limitation and a second multidimensional limitation. The first multidimensional limitation may comprise a hardware limitation for an imaging device such as a gradient amplitude limit or a gradient slew rate limit. The gradient amplitude or slew-rate limit may be calculated as a peak or as a root-mean-square limit. The second multidimensional limitation may comprise a regulatory limitation for an imaging device such as a maximum safe rate of change for a magnetic field for a scan subject. The regulatory limitation may comprise a maximum safe rate of change of a magnetic field for a scan subject in the presence of an implantable or interventional medical device. A set of desired gradient properties is provided. These gradient properties may include at least one or two of a starting gradient magnitude, an ending gradient magnitude, a net gradient area, and a higher-order gradient moment. A set of desired multidimensional gradient parameters in a first coordinate space is calculated from the provided set of desired gradient properties. The calculated set of desired multidimensional gradient parameters is transformed into a second coordinate space. A second combined constraint for the imaging device is determined by calculating an intersection between the first combined constraint and the transformed set of desired multidimensional gradient parameters. A multidimensional set of gradient waveforms that satisfy the second combined constraint is calculated. The multidimensional set of gradient waveforms will comprise a first waveform in a first axis, a second waveform in a second axis, and often also a third waveform in a third axis. It is then determined whether the first waveform, second waveform, and often the third waveform have the same time length. If the waveforms have the same time length, the multidimensional set of gradient waveforms is transformed back into the first coordinate space. If the waveforms do not have the same time length, many of the above steps may be repeated until they do. A magnetic field gradient pulse for a Magnetic Resonance Imaging (MRI) device or scanner can then be generated based on the transformed multidimensional set of gradient waveforms.

This disclosure also provides a method of generating waveforms used in an imaging application. A first imaging waveform is generated based on a first waveform schedule read from a first memory region in a computer readable medium. A second waveform schedule in a second memory region in the computer readable medium is updated while the first imaging waveform is being generated. A second imaging waveform is generated based on the second waveform schedule read from the second memory region after the first imaging waveform has finished being generated. The first imaging waveform schedule in the first memory region is updated while the second imaging waveform is being generated. The first waveform schedule and the second waveform schedule may be comprised of least one gradient waveform, RF channel waveform, shim waveform, field waveform, or acoustic waveform. The first waveform schedule and the second waveform schedule may comprise pointers to at least one waveform region, duration, amplitude, or delay interval. The time interval for generating the first imaging waveform may be the same as the time interval for generating the second imaging waveform. There may be no time delay between generating the first imaging waveform and generating the second imaging waveform.

This disclosure also provides a computer-readable medium comprising code which, when executed by a computer processor, executes a method. In a first step of this method, a set of gradient parameters from a physical gradient space is transformed, with the aid of a computer processor, into a transformed space (e.g., with at least one of a rotative transformation, a proportional transformation, a magnitude transformation, etc.). In a second step, a set of separable gradient waveforms that satisfy a set of gradient rate-of-change constraints in said transformed space is calculated, with the aid of a computer processor. In a third step, the first and second steps are repeated until the gradient waveforms in said set of separable gradient waveforms are of substantially the same time length. In a fourth step, a resulting gradient set of waveforms of substantially the same time length is transformed, with the aid of a computer processor, back into said physical gradient space.

This disclosure also provides a computer-readable medium comprising code which, when executed by a computer processor, executes a method. In a first step, an active memory region in a memory location of a computer system programmed to sequence MRI waveforms is provided. The active memory region comprises one or more waveforms and schedules being played. In a second step, one or more buffer memory regions in the memory location is provided. The one or more buffer regions comprise one or more waveforms and schedules not currently being played. In a third step, the one or more waveforms and schedules not currently being played in said one or more buffer memory regions is updated, with the aid of a computer processor of said computer system, while said one or more waveforms and schedules of said active memory region are being played. In a fourth step, said active memory region is swapped with said buffer memory region with the aid of a computer processor upon completion of the waveform playback in said active memory region.

This disclosure also provides a computer-readable medium comprising code which, when executed by a computer processor, executes a method. In a first step of the method, a time interval of a magnetic resonance imaging waveform is subdivided, with the aid of a computer processor, into one or more blocks that represent sequencing regions that are independently modifiable. In a second step, real-time changes are performed on individual blocks. The real-time changes comprise one or more of scaling, rotation, enabling, and disabling.

This disclosure also provides a computer-readable medium comprising code which, when executed by a computer processor, executes a method. In a first step of the method, a first imaging waveform is generated based on a first waveform schedule read from a first memory region of a memory location of a computer system programmed to generate waveforms. In a second step, a second waveform schedule in a second memory region in a memory location is updated while the first imaging waveform is being generated. In a third step, a second imaging waveform is generated based on the second waveform schedule read from the second memory region when the first imaging waveform has been generated. In a fourth step, the first imaging waveform schedule in the first memory region is updated.

This disclosure also provides a system for generating magnetic field gradients for use in magnetic resonance imaging (MRI). The system comprises a computer processor and a memory location coupled to the computer processor. The memory location comprises code which, when executed by said computer processor, implements a method. In a first step of this method, a set of gradient parameters is transformed, with the aid of a computer processor, from a physical gradient space into a transformed space (e.g., with at least one of a rotative transformation, a proportional transformation, a magnitude transformation, etc.). In a second step, a set of separable gradient waveforms that satisfy a set of gradient rate-of-change constraints in said transformed space is calculated, with the aid of a computer processor. In a third step, the first and second steps are repeated until the gradient waveforms in said set of separable gradient waveforms are of substantially the same time length. In a fourth step, a resulting gradient set of waveforms of substantially the same time length is transformed back into said physical gradient space.

This disclosure also provides a system for sequencing waveforms for use in magnetic resonance imaging (MRI). The system comprises a computer processor and a memory location coupled to the computer processor. The memory location comprises code which, when executed by said computer processor, implements a method. In a first step of this method, an active memory region in a memory location of a computer system programmed to sequence MRI waveforms is provided. The active memory region comprises one or more waveforms and schedules being played. In a second step, one or more buffer memory regions in the memory location is provided. The one or more buffer regions comprise one or more waveforms and schedules not currently being played. In a third step, the one or more waveforms and schedules not currently being played in said one or more buffer memory regions is updated, with the aid of a computer processor of said computer system, while said one or more waveforms and schedules of said active memory region are being played. In a fourth step, the active memory region is swapped with the buffer memory region upon completion of the waveform playback, with the aid of a computer processor.

This disclosure also provides a system for permitting real-time changes to waveforms used in magnetic resonance imaging (MRI). The system comprises a computer processor and a memory location coupled to the computer processor. The memory location comprising code which, when executed by said computer processor, implements a method. In a first step of the method, a time interval of a magnetic resonance imaging waveform is subdivided, with the aid of a computer processor, into one or more blocks that represent sequencing regions that are independently modifiable. In a second step, real-time changes on individual blocks are performed. These real-time changes comprise one or more of scaling, rotation, enabling, and disabling.

This disclosure also provides a system for generating magnetic field gradients for use in magnetic resonance imaging (MRI). The system comprises a computer processor and a memory location coupled to the computer processor. The memory location comprises code which, when executed by said computer processor, implements a method. In a first step of the method, a set of gradient parameters is transformed, with the aid of a computer processor, from a physical gradient space into a transformed space (e.g., with at least one of a rotative transformation, a proportional transformation, a magnitude transformation, etc.). In a second step, a set of separable gradient waveforms that satisfy a set of gradient rate-of-change constraints in said transformed space is calculated. In a third step, the first and second steps are repeated until the gradient waveforms in said set of separable gradient waveforms are of substantially the same time length. In a fourth step, a resulting gradient set of waveforms of substantially the same time length is transformed back into said physical gradient space.

This disclosure also provides a system for generating waveforms for use in an imaging application. The system comprises a computer processor and a memory location coupled to the computer processor. The memory location comprises code which, when executed by said computer processor, implements a method. In a first step of the method, a first imaging waveform based on a first waveform schedule read from a first memory region of a memory location of a computer system programmed to generate waveforms is generated. In a second step, a second waveform schedule in a second memory region in a memory location is updated while the first imaging waveform is being generated. In a third step, a second imaging waveform is generated based on the second waveform schedule read from the second memory region when the first imaging waveform has been generated. In a fourth step, the first imaging waveform schedule in the first memory region is updated.

In an aspect the present disclosure provides a method for generating magnetic field gradients for use in magnetic resonance imaging (MRI). The method may comprise: (a) transforming, with the aid of a computer processor, a set of gradient parameters from a physical gradient space into a transformed space; (b) calculating, with the aid of a computer processor, a set of separable gradient waveforms that satisfy a set of gradient rate-of-change constraints in said transformed space; (c) repeating steps (a)-(b) until the gradient waveforms in said set of separable gradient waveforms are of substantially the same time length; and (d) transforming, with the aid of a computer processor, a resulting gradient set of waveforms of substantially the same time length back into said physical gradient space.

The said set of gradient parameters may contain parameters that include a gradient start magnitude, gradient end magnitude, gradient amplitude, gradient first moment, and higher-order gradient moments. At least two of said parameters of said set of gradient parameters may be used. Step (c) may be nonlinear. The set of rate-of-change constraints may comprise at least one of a physical hardware constraint and a regulatory safety constraint. The said transformed space may be a result of one or more of a rotative transformation, a proportional transformation, or a magnitude transformation.

In another aspect, a method for acquiring a volumetric scan from a heart of a subject may comprise: (a) administering a precursor of a contrast agent to said subject, wherein the precursor of the contrast agent yields the contrast agent in the heart of the subject, and wherein the contrast agent is retained less in healthy myocardial tissue of the heart than in abnormal myocardial tissue of the heart; (b) applying an inversion radiofrequency (RF) pulse to the heart with the aid of an RF source of a magnetic resonance imaging (MRI) system, wherein said inversion RF pulse is applied between successive heartbeats of a cardiac cycle of said subject and within a single breath hold of said subject, and wherein said inversion RF pulse reduces or eliminates magnetic resonance (MR) signals from the healthy myocardial tissue of the heart where the contrast agent is less retained; (c) detecting magnetic resonance (MR) signals from the heart with the aid of a detector coil of said MRI system, wherein said MR signals are detected subsequent to a time delay upon applying said inversion RF pulse, and wherein said MR signals are detected between said successive heartbeats within said single breath hold; (d) storing said MR signals in a memory location as non-Cartesian data in k-space; (e) capturing an image of a slice of the heart, wherein the slice corresponds to an incomplete data set insufficient to generate a complete image of the heart; (f) repeating (b)-(e) within said single breath hold of said subject to capture a plurality of images of slices of the heart, wherein the plurality of the images of the slices correspond to a complete data set sufficient to generate the complete image of the heart; and (g) iteratively processing, with the aid of a computer processor, said non-Cartesian data corresponding to said plurality of images of slices of the heart, in a self-consistent and parallel manner, to reconstruct a three-dimensional volumetric scan, the three-dimensional volumetric scan comprising the complete image of the heart and showing enhanced contrast between the healthy and abnormal myocardial tissue. During a single cardiac cycle, said non-Cartesian data may correspond to at most 15% of the data set for generating said three-dimensional volumetric scan of the heart. MR signals may be detected from multiple regions of interest in the heart.

The method may comprise repeating (b)-(d) at least ten times within said single breath hold of said subject. The method may comprise repeating (b)-(d) at least fifteen times within said single breath hold of said subject. The method may comprise diagnosing said subject for said disease or adverse health condition based upon an assessment of said three-dimensional volumetric scan of the heart. The method may comprise generating a plurality of three-dimensional volumetric scans of the heart, wherein the plurality of scans of the heart show wash-out of the contrast agent over time from one or more of the healthy or abnormal myocardial tissues over time. The method may comprise determining intensities of a given portion of said plurality of scans; and generating a trajectory of said intensities with time based on the determined intensities. Diagnosing said subject for said disease or adverse health condition based on the assessment may comprise generating the assessment based on the generated trajectory, the trajectory indicating one or more of a rate of wash-out of the contrast agent from healthy myocardial tissue or a rate of wash-out of the contrast agent from abnormal myocardial tissue.

The method may comprise between steps (b) and (c), supplying a fat saturation RF pulse to the heart. The method may comprise in steps (c), detecting said MR signals during mid-diastole. The method may comprise repeating steps (b)-(d) at least one time within said single breath hold of said subject to generate a data set corresponding to a first post-injection time point. The method may comprise repeating steps (b)-(f) to generate a plurality of data sets, wherein each repetition of steps (b)-(f) is performed within a separate breath-hold of said subject. Each data set may correspond to a separate time point subsequent to the administering of the precursor of the contrast agent to said subject.

The non-Cartesian data may comprise one or more spirals in k-space. The non-Cartesian data may comprise a stack of spiral in k-space. An inner part of a given one of said one or more spirals may be fully sampled and an outer part of said given spiral may be under-sampled. In (g), said outer part of said three-dimensional volumetric scan may be reconstructed in said self-consistent and parallel manner. The contrast agent may comprise a hyperpolarized chemical species, paramagnetic agent, or ferromagnetic agent. The three-dimensional volume scan may be generated using generalized auto-calibrating partially parallel acquisition. Said non-Cartesian data in k-space may be iteratively processed in a self-consistent and parallel manner at an acceleration rate greater than 1. Said non-Cartesian data in k-space may be reconstructed using coil sensitivity encoding through all of said non-Cartesian data in k-space.

A signal breath hold may comprise 30 heart beats or less. A signal breath hold may comprise 15 heart beats or less. Step (f) may comprise acquiring at least five readouts within said single breath hold. Step (f) may comprise acquiring at least ten readouts within said single breath hold. Step (f) may comprise acquiring at least fifteen readouts within said single breath hold.

Left ventricular dysfunction is the result of a long list of heart diseases. Myocardial tissue characterization has long been an important focus of clinical interest. Most importantly, the assessment of myocardial viability has had very important impact on the treatment of ischemic heart disease. Late gadolinium enhancement (LGE) magnetic resonance imaging (MRI) has been used in the identification of hibernating myocardium in ischemic heart disease. LGE MRI has also found important applications in non-ischemic heart diseases, such as hypertrophic cardiomyopathy, amyloidosis, sarcoidosis, and myocarditis. In clinical decisions, LGE images have been interpreted with a relatively simple idea of “bright is dead.”

However, pathologically, most infarcted tissues are not completely dead. In fact, most non-contractile tissues contain a large amount of live myocytes and are rarely uniformly infarcted on pathologic examination. Therefore, the enhancement of scar in LGE image can be heterogeneous both spatially and temporally. Myocardial scars can be further differentiated on the basis of this heterogeneity and there may be important clinical implications based on these differences.

Spatial heterogeneity of infarct tissue can be investigated using conventional LGE MRI. Quantitative characterization of infarct core and border zones can significantly correlate with cardiac outcomes, and with ventricular arrhythmia. However, temporal variation in scar enhancement has rarely been studied due to technical limitations of the conventional LGE MRI.

An LGE imaging protocol can involve the acquisition of a two-dimensional (2D) MR image from a subject at a single location over a 10 to 15 second long breath-hold. The breath hold of the subject enables the 2D images to be taken from substantially the same area of the subject, thereby providing temporally meaningful information from the same area. In the case of ventricular imaging, this breath hold scan is repeated up to 10-14 times to cover the entire left ventricle (LV) over the course of 10-15 minutes after the contrast (e.g., gadolinium) injection.

However, this prolonged scan time for whole LV coverage may be too long to capture the dynamics of contrast uptake and wash-out accurately. Moreover, repeating this standard protocol at different post-injection times requires an excessively large number of burdensome breath-holds by the subject—data thus obtained may be inaccurate if the subject has moved in this time period, and/or the subject may experience discomfort during image acquisition.

Single breath-hold LGE imaging with whole LV coverage has been described using 2D multi-slice EPI acquisition (see Warntjes M J, Kihlberg J, Engvall J. Rapid t1 quantification based on 3d phase sensitive inversion recovery. BMC Med Imaging. 2010; 10:19) and 3DFT acquisition (see Foo T K, Stanley D W, Castillo E, Rochitte C E, Wang Y, Lima J A, Bluemke D A, Wu K C. Myocardial viability: Breath-hold 3d mr imaging of delayed hyperenhancement with variable sampling in time. Radiology. 2004; 230:845-851). However, these approaches are practically limited, due to long scan times (greater than 20 seconds) and sub-optimal spatial resolution in phase encoding and partition encoding directions.

Current methods for detecting clinical implications of infarct tissue heterogeneity using LGE MRI are based on pixel intensities of LGE images acquired at single post-injection time and a specific slice location. For example, LGE images are acquired from a single location of a heart of a subject. Although simple binary classification into core and grey zones has been useful for the prediction of future cardiac events, this “static” approach lacks the consideration of “dynamic” wash-out kinetics and may be misleading due to the single time sample taken. Furthermore, not all the slices are obtained at the same time point, which may lead to further classification errors.

The present disclosure provides systems and methods that overcome various limitations of LGE Mill methods currently available. Methods provided herein enable early-to-late Gadolinium enhancement (ELGE) MRI, which provides the capability of capturing temporal change, which provides the ability to better describe and characterize the degree of inhomogeneous tissue viability. This information can advantageously improve prediction of functional recovery, ventricular remodeling and generation of arrhythmia.

3D imaging methods of the present disclosure also advantageously enable image registration between data sets from different post-injection times. The accurate registration of time-resolved image sets may be necessary to perform subsequent qualitative and/or quantitative analysis efficiently. Since a 3D image is acquired from single breath-hold per each time frame, and through-plane motion can be corrected as accurately as in-plane motion (as opposed to 2D multi-slice images), the compensation for different breath-hold positions can be corrected for accurately using a 3D rigid-body model.

Methods of the present disclosure can be used as an alternative to conventional LGE MRI at single late post-injection time. Given the short scan time for entire LV coverage, optimal inversion delay time and post-injection time for complete nulling of healthy myocardium could be easily accommodated.

In some situations, upon acquiring time series of 3D data, temporal wash-out kinetics can be seen by playing the time series of 3D data in video format (i.e., images as a function of time). Quantitative analysis can be at least minimally performed by generating time-intensity curves of manually specified regions of interest (ROIs), and fitting them to gamma-variate model. Raw time curves and fitting parameters can demonstrate different temporal behaviors within the scar region. More systemic ways to quantify the wash-out kinetics can be performed to improve inter-observer reliability. One potential approach can be absolute quantification of contrast uptake. This analysis can require additional steps, such as conversion from raw intensity to contrast concentration and input function measurement from LV blood pool.

There are several variations of the proposed technique that can be helpful depending on the clinical scenario. Data can be acquired R-R interval of a cardiac cycle (a′ denotes the start of a systolic phase), which may advantageously minimize the breath-hold of a subject. However, in the presence of severe R-R variation or arrhythmia, recovered longitudinal magnetization before the inversion pulse can vary, which can cause image artifact and suboptimal image contrast due to k-space modulation. Use of two R-R intervals improves robustness to the R-R variation, but increases total scan time as a trade-off. In subjects with arrythmia, data acquisition every 2 R-R intervals may be used along with higher acceleration rate (>1, 2, 3, 4, or 5) of parallel imaging reconstruction.

Further, 3D imaging data may require optimization for spatial variation of receiver coil sensitivity. An approach provided herein is to normalize raw ELGE images with low resolution, proton density weighted images acquired using small flip angle with little to no magnetization preparation.

In some embodiments, imaging is performed at one minute temporal resolution, which may be adequate to capture the contrast dynamics. However, in some cases, the temporal resolution can be shortened to 30-40 sec by allowing a rest period of 20-30 sec between two consecutive scans.

The present disclosure provides a method for acquiring a volumetric scan from at least a portion of a body of a subject suspected of exhibiting an observable manifestation of a disease or adverse health condition. The at least the portion of the body of the subject can comprise a heart of the subject. The method comprises applying an inversion radiofrequency (RF) pulse to the at least the portion of a body of the subject with the aid of an RF source of a magnetic resonance imaging (MRI) system, and detecting magnetic resonance (MR) signals from the at least the portion of the body of the subject with the aid of a detector coil of the MRI system. The inversion RF pulse can be applied between successive heartbeats within a single breath hold of the subject. The MR signals can be detected subsequent to a time delay upon applying the inversion RF pulse. The MR signals can be detected between the successive heartbeats. Next, the MR signals can be stored in a memory location (e.g., database) as non-Cartesian data in k-space. This can be repeated at least 1, 2, 3, 4, 5, 6, 7, 8, 9, 10, 11, 12, 13, 14, 15, 20, 30, 40, 50, 100, 200, 300, 400, 500 times within the single breath hold of the subject. In some cases, this is repeated over at least 1, 2, 3, 4, 5, 6, 7, 8, 9, 10, 15, 20, 30, 40, 50, or 100 cardiac cycles within a single breath hold of the subject.

Another aspect of the present disclosure provides a method for acquiring a volumetric scan from a heart of a subject, comprising (a) applying an inversion RF pulse to the heart of the subject, wherein the inversion RF pulse is applied between successive heartbeats of a cardiac cycle of the subject and within a first single breath hold of the subject; (b) detecting MR signals from the heart of the subject, wherein the MR signals are detected subsequent to a time delay upon applying the inversion RF pulse, and wherein the MR signals are detected between the successive heartbeats; (c) storing the MR signals in a memory location as non-Cartesian data in k-space, (d) repeating (a)-(c) at least one time within the single breath hold of the subject to generate a data set corresponding to a first post-injection time point and (e) repeating (a)-(d) to generate a plurality of data sets, wherein each repetition of (a)-(d) is performed within a separate breath-hold of the subject. Each data set can correspond to a separate time point subsequent to the injection of a precursor of a contrast agent to the subject. Each data set can include non-Cartesian data in k-space.

Another aspect of the present disclosure provides a method for acquiring a three-dimensional volumetric scan from a subject using MRI. The method comprises acquiring, with the aid of an MRI system, a plurality of time-efficient non-Cartesian readouts from the subject within a single breath hold of the subject. The single breath hold can comprise 100, 90, 80, 70, 60, 50, 40, 30, 20, 10, or 5 heart beats or less. In some cases, the method comprises acquiring at least 5, 10, 15, 20, 30, 40, 50, 60, 70, 80, 90, 100, or 500 readouts from the subject within the single breath hold of the subject.

Another aspect of the present disclosure provides a computer system for acquiring a volumetric scan from at least a portion of a body of a subject suspected of exhibiting an observable manifestation of a disease or adverse health condition. The computer system comprises a memory location that stores (i) pulse data corresponding to one or more RF pulses applied to the at least the portion of the body of the subject between individual heart beats of the subject, and (ii) signal data corresponding to MR signals acquired from the at least the portion of the body of the subject during a single breath and within 60 heart beats or less. Within a data acquisition time interval an MR signal of the signal data is subsequent in time to an RF pulse of the pulse data within the given data acquisition time interval, and the signal data comprises non-Cartesian data in k-space. The computer system can further comprise one or more computer processors coupled to the memory location. The one or more computer processors can process the non-Cartesian data retrieved from the memory location to generate an image or intensity profile(s) with time (e.g., trajectory of intensity, velocity of intensity) of the at least the portion of the body of the subject. The at least the portion of the body of the subject can include a region of interest (ROI), such as a tissue or a portion of a tissue.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings of which:

FIG. 1 schematically illustrates a two-dimensional example of the safety and hardware limitations for maximum magnetic field gradient rates-of-change permitted in MRI. The areas where permitted safety and hardware areas overlap represent the space of allowable rates of magnetic field gradient rates-of-change and thus define the maximum range of possible slew rates.

FIG. 2 shows an example of a design process wherein an efficient Cartesian readout gradient is designed with specified areas, start amplitudes, and end amplitudes.

FIG. 3 is a flow chart of an exemplary process described herein for the design of time-efficient gradient waveforms.

FIG. 4 describes an exemplary set of simplifying transformation and rotation elements of the present invention used to calculate time-optimal magnetic field gradient waveforms in a two-dimensional example. In (a) (b) and (c), physical gradient axes (Gx, Gy) and logical gradient axes (Gx′, Gy′) overlap. In (d) (e) and (f), these coordinate systems differ. In (a) and (d), an additional rotation is introduced to create a transformed space in which to apply separable gradient design techniques. Alternatively, (b) and (e) show a proportional approach that can be applied to provide an alternative separable transform space. Finally, (c) and (f) show a magnitude-based simplifying transform that is not separable but nonetheless can simplify some designs. In each case, the shaded region indicates a combined, simplified safety/hardware constraint in the transformed space.

FIG. 5 describes physical magnetic field gradient waveforms calculated as a function of time using the present invention in a three-dimensional example.

FIG. 6 describes the point-wise magnetic field gradient change limits of the waveforms shown in FIG. 5. The average data point is at 93% of the theoretical limit.

FIG. 7 is a conceptual schematic describing the computer memory architecture that may be used in Mill sequencing hardware. A scheduler for each waveform axis plays waveforms uploaded into a waveform library. The scheduler may make simple transformations such as bulk amplitude changes, duration changes, phase/rotation changes, or changes to which waveform in the library the scheduler may be pointing.

FIG. 8A schematically shows a waveform sequence execution from hardware computer memory. Waveforms may be played from computer memory using the scheduler. Following playback, the scheduler may be serially updated in the computer memory during a period of waveform inactivity. The switching of waveform sequence playback and scheduler update may repeat until an imaging sequence is completed. FIG. 8B schematically depicts a waveform sequence of the invention. Waveforms may be played in an active memory region while the required updates to both the waveform library and scheduler for a future sequencing interval (TR) may be concurrently uploaded into a separate buffer region. The active region may be swapped with the buffer region corresponding to the next TR and that buffer region then may be played as the new active region, whereas the former active region may now function as a buffer region for a subsequent playback period.

FIG. 9 shows a single TR of a spiral flow-encoded pulse sequence showing an example of how a TR interval may be divided into three distinct blocks.

FIG. 10 shows an early-to-late gadolinium enhancement (ELGE) method of the present disclosure.

FIG. 11 shows a schematic pulse sequence of a three-dimensional (3D) early-to-late gadolinium enhancement (ELGE) imaging method of the present disclosure. After inversion magnetization preparation, a trigger delay (TD) and inversion delay time (TI), segmented 3D spiral acquisition can occur at mid-diastole.

FIG. 12 shows a stack-of-spiral k-space trajectories for 3D data acquisition. Per each k_{z} level, an inner part of spiral is fully sampled and outer part of it is two-fold under-sampled. These under-sampled 3D data can be reconstructed using an iterative self-consistent parallel imaging reconstruction (SPIRiT).

FIG. 13 shows a system configured to implement methods of the present disclosure.

FIG. 14 shows an imaging device configured to implement methods of the present disclosure.

FIG. 15A shows 3D ELGE images from a subject with myocardial infarction, taken at 2 minutes after contrast administration. The region of scar on anteroseptal wall appears darker than the remote region due to lower perfusion. FIG. 15B shows LGE images from a subject myocardial infarction, taken at 2 minutes after contrast administration. Late enhancement signals are homogeneous over entire myocardium.

FIG. 16A shows a mid-short-axis slice of 3D ELGE images acquired at post-injection times of 2 min, 5 min, and 8 min. FIG. 16B shows the data of FIG. 16A displayed by color scale. Harsh display window is used for color images for better visualization of the evolution of scar enhancement. FIG. 16C is a two-dimensional (2D) image from a commercial LGE sequence at the same slice location.

FIG. 17 shows time-intensity curves (solid lines) of three representative region-of-interests (ROIs) in mid-short-axis ELGE images, and their gamma-variate fits.

### DETAILED DESCRIPTION

While various embodiments of the invention have been shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

The term “breath hold,” as used herein, generally refers to a physical state of a subject in which the subject is holding his or her breath. In some cases, during a breath hold the subject is not inhaling or exhaling.

The term “kinetic,” as used herein, generally refers to changes in the contrast (brightness and darkness) in a given region of a body of subject being interrogated.

### Magnetic Gradient Generation

Gradients used in MRI may be generated by amplifiers that drive coils to produce spatially varying magnetic fields oriented along a set of physical axes fixed to the MRI system geometry. A gradient subsystem may be comprised of three amplifiers and corresponding coils, each set directed along one of three perpendicular axes.

The gradient fields produced by the gradient amplifiers/coils may be defined by “waveforms” (gradient level with respect to time) calculated along three “physical” perpendicular axes by an associated computer. When creating an image, the gradients that are required typically are specified in the coordinate system of the image to be acquired; these perpendicular left-right, up-down, and through-plane image directions can be considered as a second set of “logical” coordinate axes (x′, y′, z′). These logical axes may not correspond to the physical axes on which the MRI system's gradient amplifiers/coils may be arranged, in order to allow for arbitrary imaging orientations. As a result, each logical gradient waveform may be executed using a combination of one or more of the system's physically oriented gradients, depending on the desired imaging orientation. When a pulse sequence is executed, the logical gradient waveforms may be converted into physical gradient waveforms for driving the gradient amplifiers on the Mill system. Such conversion may be achieved by matrix rotation of the logical gradient waveforms.

The magnetic field gradient subsystem of an MRI system is critical in defining the utility of a scanner. In general, more powerful gradient subsystems may provide greater applications capability. The power of a gradient subsystem may refer to the limits on allowable gradient amplitude, allowable gradient slew rate, or some combination of the two. The gradient amplitude is the magnitude of linear magnetic field variation that the gradient amplifiers produce in the gradient coils (typically expressed in Gauss per centimeter, G/cm), and the gradient slew rate is the rate at which the gradient amplifiers can change the gradient amplitude (typically expressed in G/cm per millisecond, G/cm/ms). For reference, various MRI scanners may be capable of maximum gradient amplitudes between 2 and 5 G/cm, and maximum slew rates between 7 and 25 G/cm/ms.

In at least some circumstances, the attribute of importance in the generation of a gradient field pulse may be the integral of gradient amplitude over the duration of the gradient pulse (i.e., the gradient pulse area). This area may be desirable on either the physical or logical axes, but is most typically specified along logical axes. For example, creating a linear phase distribution in tissues along a certain image axis can be accomplished equivalently through generating a certain gradient area along that axis, roughly regardless of the particular wave shape that was used to generate that area. In other circumstances, the first moment of the pulse over time may also be important (e.g., the integral of the gradient amplitude multiplied by time over the duration of the gradient pulse). This concern for areas and/or gradient moments may be utilized across a wide variety of MRI acquisition techniques, including, for example, slice-select refocusing, phase-encoding, velocity or flow compensation, crushing, spoiling, rewinding and readout defocusing gradient pulses. Since the shortest duration gradient pulse of a given area may provide the greatest flexibility in selecting pulse sequence echo time (TE) and pulse sequence repetition time (TR), it may be desirable for the MRI system to produce these gradient pulses with the minimum pulse duration possible given the prescribed pulse area and/or moment.

Magnetic field gradients may be switched on and off during a pulse sequence to encode different positional information, to prepare magnetization, and to create steady states. Indeed, a large portion of the time required for MRI may include waiting for gradient waveforms to reach specified values (e.g., net area, moments, amplitudes) in the gradient hardware. Thus, the speed at which an MRI image may be produced may directly depend on how quickly gradient waveforms can reach their specified values. Therefore, significant value may exist in computing time-efficient gradient waveforms in a time efficient manner, as it may help to minimize gradient switching times and, thus, the overall speed of image acquisition. Moreover, it may be beneficial to be able to quickly recalculate gradient waveforms, often in response to user inputs, such as selection of a new scan-plane geometry, adjusting image field-of-view, slice thickness, etc.

In addition to magnetic field gradients, other components of a pulse sequence may also be defined by a waveform. These components include, but are not limited to, the RF pulse used to excite nuclear spins and shims used to correct for inhomogeneities in the applied static magnetic field, B₀.

After the various waveforms necessary to complete an imaging sequence are computed, they may be properly sequenced. For this process, a schedule (the “scheduler”) that accurately assembles the sequence of waveforms and other parameters that may be needed to execute a pulse sequence and a library of pre-determined waveforms may be uploaded into a piece of sequencing hardware (the “sequencer”) memory for execution in the respective sub-devices (e.g., gradients, RF coil, etc.) of the MRI system. Sequence events played during a pulse sequence may repeat, repeat with changes, repeat in a cycling manner, or be fairly different from one to the next depending on the pulse sequence(s) used. As an example, a real-time imaging application may desire to update the image field-of-view or RF tip angle dynamically in response to a user request (e.g., by moving the associated sliders in the user interface). The full gamut of such changes could not be anticipated ahead-of-time, and the waveforms and sequencer must be updated, the new sequence played, and the data must be reconstructed and displayed all within hundreds of milliseconds in order for the user to perceive a responsive, low-latency user interface.

In current implementations known in the art, sequencer changes may only occur at regular intervals during certain serial “dead-time” portions of the pulse sequence, where scheduler playback may not occur. Such a serial approach may introduce inefficiency into a pulse sequence, as a period of sequencer inactivity may be required for proper playback, and the number of allowable changes per interval may be limited by the duration of the dead period. Moreover, any additional waveforms not known prior to the start of sequence execution and, thus, not included in the uploaded library may also require additional dead-periods for additional waveform uploading. It should also be noted that in cases where sequencing occurs only during a dead-period, the flexibility of the sequencer to appropriately implement any unexpected waveform changes in real-time is limited.

This disclosure provides systems and methods for improving the performance of magnetic resonance imaging (MRI) systems. The disclosure also provides methods to generate magnetic field gradient waveforms that may be used in MRI, that may conform to hardware and safety constraints with respect to gradient rate-of-change, that may be minimal duration, that may be developed in an efficient and intuitive interface, that may be calculated efficiently, and that may be sequenced in a rapid, time-efficient manner that may be readily adaptable to unanticipated changes in a pulse sequence. Moreover, the sequencing methodology may be extended to any arbitrary waveform used in MRI.

Methods and systems of the disclosure may be advantageously fast to compute, and arrive very or substantially nearly to the true optimal solution that may be computed using much more time-consuming methods. Moreover, the approach may allow fast gradient pulses to be used across most, if not all, MM applications, including the design of pulse sequence applications where the multidimensional gradient area, moment, start, and end amplitudes may be the desired input parameters.

### Time-Efficient Constrained MRI Gradient Waveforms

Magnetic field gradients may be a critical component of MRI scans, as they are largely responsible for encoding spatial positions for creating images. These gradient fields in some cases may be switched on and off to encode different positional information, to prepare magnetization, and to create steady states. The speed at which these transitions can occur may directly impact the overall speed of the Mill acquisition.

At least two independent limits may be applicable in determining how quickly gradient fields can be switched. A first independent limit may be a physical hardware limit, which constrains the gradient slew rate to a specific value or range of values on each physical gradient axis. Further limits on the gradient parameters may be imposed by hardware constraints, including, but not limited to, physical heating of the gradient coils and/or amplifiers, performance characteristics of the gradient amplifiers, etc. A physical limit may exist for both gradient amplitude and also gradient slew rate. In the case of gradient slew rate, the allowable slew rate at any given instant may be a function of the gradient amplitude using for example the gradient “voltage model” known in the art. Further limits on the gradient parameters may be imposed by other hardware constraints, including, but not limited to, physical heating of the gradient coils and/or amplifiers, performance characteristics of the gradient amplifiers, etc.

A second independent limit may be a safety limit, as imposed by regulatory agencies. The safety limit may specify the maximum rate of change of magnetic field (dB/dt) that can be tolerated by a scan subject (e.g., patient), often based on a set of equations that describe the response of peripheral and cardiac nerve stimulation as a function of dB/dt and pulse duration. As a result, the safety limit may depend upon the size of the magnet or strength of the applied magnetic field, duration of the stimulus, and other factors. This is described in detail in IEC 60601-2-33, an international regulatory standard accepted by the U.S. Food and Drug Administration (FDA) and other regulatory bodies, which is entirely incorporated herein by reference.

Each of the hardware limits may be expressed as a limitation on the gradient (Gₓ, G_{y}, and G_{z}) and gradient slew rate (i.e., the gradient rate-of-change—G′ₓ, G′_{y}, and G′_{z}) in each physical direction. In typically the most straightforward view of these hardware constraints, the hardware limits may be expressed as an absolute limit operating on each of three Cartesian axes independently:

Gₓ<G_{x,max,hardware}

G_{y}<G_{y,max,hardware}

G_{z}<G_{z,max,hardware}

G′ₓ<G′_{x,max,hardware}

G′_{y}<G′_{y,max,hardware}

G′_{z}<G′_{z,max,hardware}

whereas the safety limit may be defined by an inseparable elliptical constraint, based on just the slew rate in each direction:

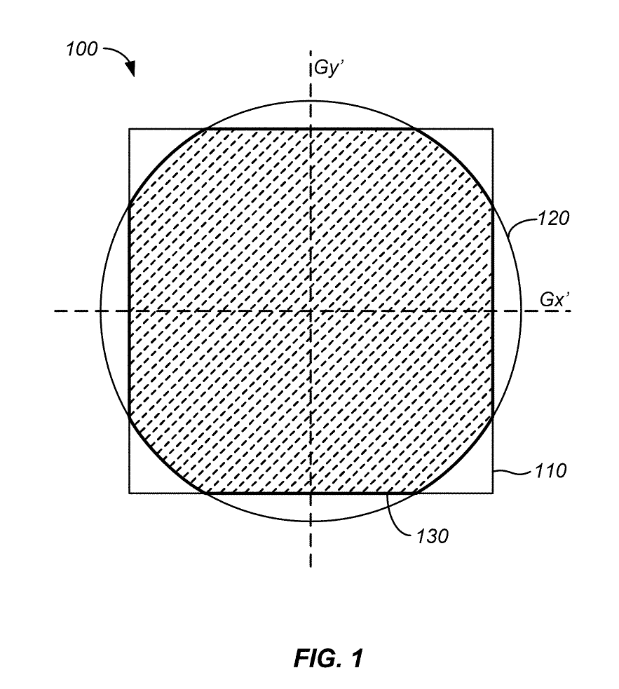

(wₓG′ₓ)²+(w_{y}G′_{y})²+(w_{z}G′_{z})²<G′_{max,safety},

where wₓ, w_{y}, and w_{z}, represent axis-specific weighting factors. Using this model and considering only two dimensions, FIG. 1 depicts a combined constraint 100 of gradient hardware and safety limits. The box 110 shown in FIG. 1 represents the hardware limit, the circle 120 represents the safety limit, and the area of overlap (hatched region 130) between the box and the circle represents a combined limit. The combined constraint shown in FIG. 1 may indicate the range of acceptable rates of change of gradients. In three dimensions, this range may represent the region of intersection between a three-dimensional ellipsoid and a three-dimensional rectangular box.

If the gradient hardware is of low-performance, then the hardware limit may not extend beyond the safety limit at any point, and a rectangular box 110 representing the hardware limitation may be the overall constraint. Conversely, for high-performance hardware, the hardware limit may exceed the safety limit in all directions and, thus, the overall constraint may be the ellipsoid or circle 120 that defines the safety limitation. Most often for a given system, though, the combined constraint falls between these two extremes. This may be due to the significant expense of gradient systems, as it may not be economically viable to engineer these systems to be capable of much more than the regulatory limit. Therefore, a complicated gradient waveform optimization may be performed in order to minimize the time required for gradients to reach their desired values, and, thus, the speed of an MRI acquisition.

The optimization becomes more complicated still when the full mathematical constraints are considered, where for the safety case, a higher slew rate may be acceptable for a shorter duration, and for the hardware case, a higher gradient rate of change may be possible if the gradient magnitude is lower than its correctly biased full-scale.

Because these constraints do not follow a simple formula but rather are typified by the piecewise, combined constraint as depicted in FIG. 1, it can be quite challenging to derive a globally optimal solution under such a constraint, particularly when a larger number of desired waveform attributes must be simultaneously met. To arrive at a tractable, unique solution, a simplification may be desired.

To optimize gradients in a time-efficient manner under these constraints using methods provided herein, the gradient properties that may be needed for a corresponding set of waveforms on each axis (e.g. x, y, and z) may be parameterized. Such properties may include the starting gradient magnitude (sₓ, s_{y}, and s_{z}), ending gradient magnitude (eₓ, e_{y}, and e_{z}), net gradient area (Aₓ, A_{y}, and A_{z}), and various gradient moments (M_{n,x}, M_{n,y}, and M_{n,z}, denoting the nth gradient moment). A subset of at least two of these values may be specified on each axis to ensure a relevant solution. For at least some imaging problems, these properties may represent the complete range of desired gradient manipulations.

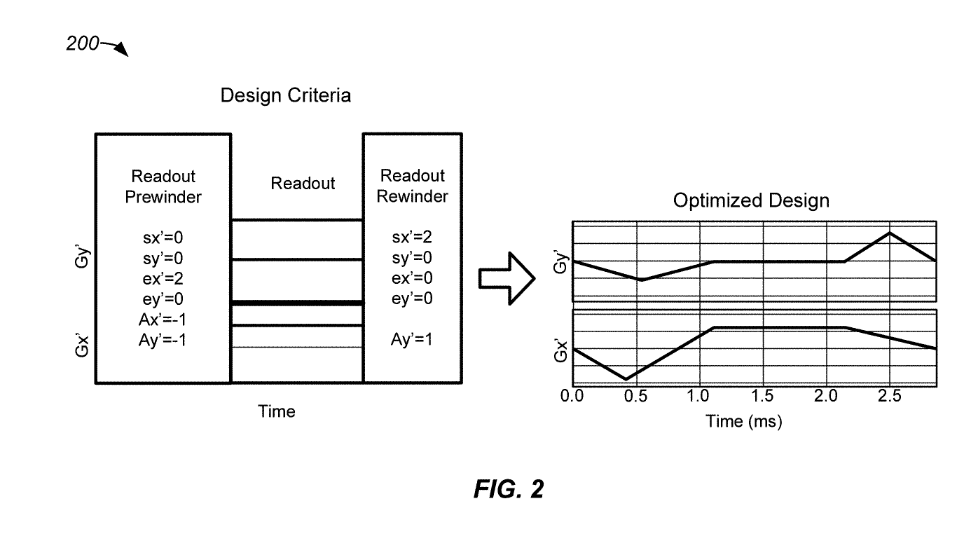

For example, consider the typical 2-dimensional Cartesian readout design problem 200 depicted in FIG. 2. The fundamental requirement of the Cartesian readout 200 is the readout plateau, with a constant gradient amplitude on the Gx′ gradient axis for a specified duration (in this example, the duration is 1 ms and the amplitude is 2 G/cm). Prior to that plateau, a so-called set of ‘prewinder’ gradients is necessary. The waveform shapes themselves are not important, but the waveforms must start from zero amplitude on both axes and end with Gx′ at 2 G/cm and Gy′ at 0. In addition, these gradients must have areas given by formulae known in the art; for the sake of example, say these are Ax′=−1 G/cm/ms and Ay′=−1 G/cm/ms. Similarly, after the readout plateau, a set of ‘rewinder’ gradients must be provided. In this example, they might be specified with initial amplitudes sx′=2 G/cm, sy′=ex′=ey′=0, and the Y′ rewinder gradient should have a total area of 1 G/cm/ms. In this case, the total area of the X′ rewinder is not of interest to us and can be left unspecified. The design challenge would be to create the fastest set of gradient waveforms that meet all of these criteria. Such a set of waveforms is depicted at the right of FIG. 2. The following discussion describes how we might accomplish this design process.

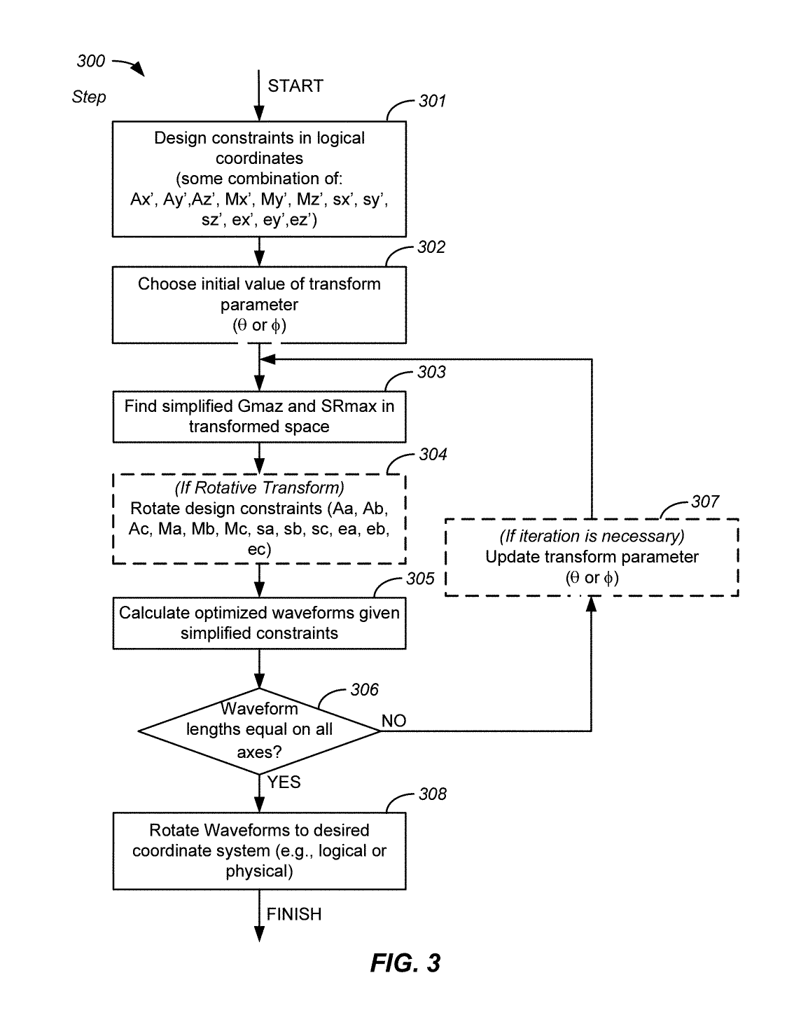

The flow chart of FIG. 3 describes an embodiment of an iterative design process that may be used to rapidly design optimal and near-optimal gradient waveforms. The description in this paragraph is merely an overview of the entire process; additional details will be provided over the course of subsequent sections. As a first operation 301, a set of multidimensional design constraints (s_{x′}, s_{y′}, s_{z′}, e_{x′}, e_{y′}, e_{z′}, A_{x′}, A_{y′}, A_{z′}, M_{n,x′}, M_{n,y′}, M_{n,z′}, or some subset thereof) is determined using techniques in the art and based upon the requirements of the imaging technique being employed. As a second operation 302, a transform parameter (to be used as a variable of iteration) is initialized to some value. This initial value may be chosen at random or may be selected based upon some heuristic or educated estimation based upon the design constraints. As a third operation 303, that parameter is used to arrive at a set of simplified design limits Gmax and Smax, where the simplified limits conform to a well-defined geometric relationship such as a rectangular box or spheroid. As a fourth operation 304, in the case of rotative transformations defined below, the design constraints are rotated into the rotative transform space. As a fifth operation 305, optimized waveforms are generated using these simplified constraints. As a sixth operation 306, the resultant waveforms are tested for equal length (or any other parameter that can be left unfixed as a surrogate for length, such as relative gradient magnitude, residual area, residual moment, duration of a sub-component of the waveform, etc.). If all designed waveforms have equal length, then the iteration is considered finished; if not, then the transform parameter is appropriately updated (seventh operation 307) and we return to operation 303. After iteration completes, the resultant waveforms may or may not be rotated in an eighth operation 308 into a desired coordinate space—often, this involves transformation into physical waveforms to be used to drive the gradient hardware.

In some embodiments, parameterized gradient properties may be transformed into an alternative coordinate space, which may be denoted as a “rotative” space. This space may be denoted by axes a, b, and c. Gradient properties may be transformed with the aid of systems of the disclosure, which can include one or more computer processors. To start, the transformation between logical axes (x′,y′,z′) and (a,b,c) may be arbitrarily chosen. In matrix notation, each gradient property may be rotated using the rotation matrix that specifies the transformation between the (x′,y′,z′) and (a,b,c) coordinate systems. In this transformed coordinate system, a safe set of gradient rate-of-change limits, inscribed within the original combined constraint, may be defined that represents the maximum separable gradients possible given the combined constraint. A separable constraint is represented by a rectangle (2D) or rectangular box (3D) oriented in the (a,b,c) space. The dimensions of this box should be chosen to ensure that no portion of the box exceeds the combined original constraint, while maximizing either the area of the box, the combined axis lengths, or some other size metric on the box. Preferentially, the area of the box should be maximized such that it is inscribed within the combined constraint.

For example, if the rate-of-change limits for a given transformed space are constrained by a spherical safety limit |SR_{max,safety}| alone, then a separable constraint for that situation could be described by:

$${SR}_{ma x , a} = {SR}_{ma x , b} = {SR}_{ma x , c} = \frac{\vert {SR}_{ma x , safety} \vert}{\sqrt{3}}$$

The maximum slew rates on each axis here have been chosen such that they are equal to one another. An example of the application of a similar constraint for two dimensions is shown in FIG. 2.

In this example, the (a,b) coordinate system is rotated by an angle θ from the logical (x′,y′) system. In this particular example, the rotation matrix is:

$$[ \begin{matrix}cos θ & - sin θ \\ sin θ & cos θ\end{matrix} ]$$

Points (x′,y′) in the logical space can be transformed into the (a,b) space using the matrix equation:

$$[ \begin{matrix}a \\ b\end{matrix} ] = [ \begin{matrix}cos θ & - sin θ \\ sin θ & cos θ\end{matrix} ] [ \begin{matrix}{x}^{′} \\ {y}^{′}\end{matrix} ]$$

In this example, the separable constraint is dictated by the global safety constraint given by SR_{max,a}²+SR_{max,b}²≤SR_{max,safety}²,

the separable-constraint area is maximized by an inscribed square with side length given by:

$${SR}_{ma x , a} = {SR}_{ma x , b} = \frac{\vert {SR}_{ma x , safety} \vert}{\sqrt{2}}$$

Note that the square root here differs from the above equation because it is a two-dimensional example.

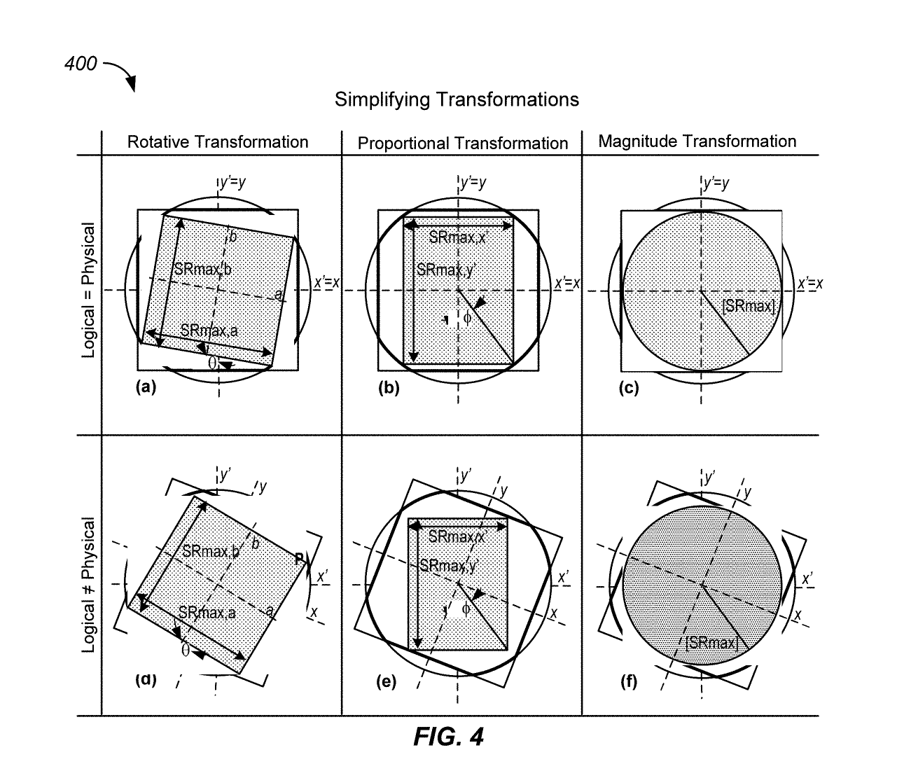

In the coordinate space of the rotated box, side lengths are constrained so that each corner vertex intersects with the global safety constraint. In one example of transformed spaces 400 shown in (a) of FIG. 4, the allowed gradient rates of change in the transformed space correspond to the dark shaded region of the rotated box circumscribed by the safety limit circle. For the sake of simplicity, the coordinate space in (a) has been set so that logical and physical coordinate systems are the same (x,y,z)=(x′,y′,z′). The more general case, where logical and physical coordinates are not coincident, is shown in (d) of FIG. 4.

In other embodiments, a transformed space may be chosen through proportionate selection of limits along the cardinal logical axes rather than by an additional rotation. This case, depicted in (b) of FIG. 4 for the simplified case where logical and physical coordinates are equivalent, permits the selection of unique limit maxima along each logical axis. In the case of gradient magnitude limits, these could be denoted with (Gmax,x′, Gmax,y′, Gmax,z′) and in the case of slew-rate limits, (SRmax,x′, SRmax,y′, SRmax,z′). To facilitate creation of this type of transform and later iteration, an angle ϕ may be selected as shown in (b), and the corner of the box chosen to conform to the minimum limit at that angle from the origin. For the example shown, with safety limits being the operable limit in that case, the limits would be:

SR_{max,x′}=2|SR_{max,safety} sin(ϕ)|

SR_{max,y′}=2|SR_{max,safety} cos(ϕ)|

A more generalized case for this type of transformation, where logical and physical coordinate axes are not equivalent, is shown in (e) of FIG. 4. Note that in this transformation, the axes of the box do not rotate along with the physical axes and therefore a different set of limits may be operative. In the case depicted, the new logical frame leads to new limits that are dictated by the hardware slew limits rather than the safety limits.

In still other embodiments, a simplifying transform may be applied that limits created gradients based upon a magnitude or spheroidal constraint. This case is depicted for two dimensions in (c) of FIG. 4 for coincident logical and physical axes, and in (f) of FIG. 4 for unequal logical and physical axes. For a spheroidal constraint, axes of the spheroid may be chosen along physical axes x,y,z in which case the slew rate constraint would be:

$$\frac{{SR}_{x}^{2}}{min {( {SR}_{x , ma x , hardware } , \frac{{SR}_{ma x , safety}}{{w}_{x}} )}^{2}} + \frac{{SR}_{y}^{2}}{min {( {SR}_{y , ma x , hardware } , \frac{{SR}_{ma x , safety}}{{w}_{y}} )}^{2}} + \frac{{SR}_{z}^{2}}{min {( {SR}_{z , ma x , hardware } , \frac{{SR}_{ma x , safety}}{{w}_{z}} )}^{2}} \leq 1$$

This choice of constraint may not allow separable design as the gradient limits in one axis are affected by gradients on the other axes. However, well defined solutions for common problems exist for spheroidal constraints, so in many cases a closed-form solution exists. As an example, take the simplified 2D case depicted in (c) or (f). Because the hardware constraint is smaller than the safety constraint on both physical axes, |SRₘₐₓ|=SR_{max,hardware}. Using this magnitude transformation, a set of optimized waveforms for the readout rewinder of FIG. 2 can be derived. On the x′ axis, the length of the final waveform is given by

$$\frac{{s}_{{x}^{′}}}{{SR}_{{x}^{′}}} = L ,$$

where L is the length of the waveform and SRₓ²+SR_{y′}²≤SR_{max,hardware}² as a result of applying the above slew rate constraint equation, and noting that the slew rate constraints can be applied in the logical frame because of the circular constraint boundary. On the y′ axis, a similar equation for L can be derived assuming a triangular waveform:

$$2 \sqrt{\frac{{A}_{{y}^{′}}}{{SR}_{{y}^{′}}}} = T$$

It is often desired these times T to be equal on all axes, so setting these equations equal to one another and solving for SRy′ results in:

$${SR}_{{y}^{′}} = \frac{- {s}_{{x}^{′}}^{2}}{8 {A}_{{y}^{′}}} + \sqrt{\frac{{s}_{{x}^{′}}^{4}}{64 {A}_{{y}^{′}}^{2}} + {SR}_{ma x , hardware}^{2}}$$

Assuming a SRmax,hardware of 9.5 G/cm/ms and other parameters from FIG. 2, this equation can be solved to find SRy′=8.99 G/cm/ms and SRx′=3.08 G/cm/ms. These slew rates lead to waveforms with total duration T=0.65 ms. Note that in this solution, iteration was not required to arrive at a solution with equal durations on all axes.

The choice between these three transform spaces may be arbitrarily made, and indeed the optimized gradients that result are often similar in performance. The proportional transformation (in (b) and (e)) can be advantageous because it allows for post-hoc scaling of logical gradient waveforms. More specifically, often a gradient scaling operation occurs from repetition to repetition along a specific axis, as may typically occur in Cartesian phase-encoding gradients known in the art. These phase-encoding gradients would typically be implemented by scaling (reducing) gradients along the logical Gy′ axis while leaving the Gx′ magnitude unaltered. Looking at point P in (d), one can see that such a Gy′ reduction without changing Gx′ could easily lead to a parameter value outside of the allowable combined constraint. Conversely, when using the proportional or magnitude transformation approaches, any scaling along x′ and y′ axes can be accommodated and is certain to be within the combined constraint. Thus, this method is more generally useful in cases where gradient scaling is desired after the gradient-design stage. Furthermore, the proportional and magnitude methods are more amenable to composing gradients where different types of limits are desired on different axes, like having a gradient area constraint on one axis but only gradient start and end constraints on other logical axes. The operation of transforming the constraints cannot be efficiently performed in the rotative-transform space.

Regardless of the transform space chosen (rotative, proportional, or magnitude), time-optimal gradient waveforms may be calculated by iterating over the full range of its transform parameter (θ for rotative transforms, or φ for proportional ones; iteration may or may not be necessary for magnitude transforms). A flowchart of the process 300 is given in FIG. 3.

The combined constraint with respect to the transformed space may be solved symbolically for each case where some subset of areas, gradients, start, and end magnitudes are desired.

As an example, consider again the Cartesian Readout of FIG. 2. To design the rewinder block, a simple ramp is required on the X′ axis, and a trapezoid or triangle is required on Y′. The duration of the X′ ramp can be calculated for a known slew rate SRx′ using:

$${T}_{{x}^{′}} = \frac{{s}_{{x}^{′}} - {e}_{{x}^{′}}}{{SR}_{{x}^{′}}}$$

Using the values in the example and given a slew rate SRx′=3 G/cm/ms, the duration Tx′ for this ramp iteration would be 2/3 ms. Note that this result is extremely similar to the result determined using the magnitude transformation above.

On the Y′ axis, a specified area Ay′ is needed, so a simple ramp is not sufficient. Assuming a triangle waveshape would suffice, the area of which can be derived as:

$${A}_{{y}^{′}} = ( \frac{{s}_{{y}^{′}}}{2} + ( {s}_{{y}^{′}} + {SR}_{{y}^{′}} \frac{{T}_{{y}^{′}}}{2} ) + \frac{{e}_{{y}^{′}}}{2} ) \frac{{T}_{{y}^{′}}}{2}$$

Rearranging terms and using the quadratic formula to solve for Ty′, we arrive at:

$${T}_{{y}^{′}} = \frac{3 {s}_{{y}^{′}} + {e}_{{y}^{′}}}{2 {SR}_{{y}^{′}}} \pm \frac{\sqrt{{( \frac{3 {s}_{{y}^{′}} + {e}_{{y}^{′}}}{2} )}^{2} + 4 {A}_{{y}^{′}} {SR}_{{y}^{′}}}}{{SR}_{{y}^{′}}}$$

For the values in the example and given a slew rate SRy′=9 G/cm/ms, the duration Ty′ for this iteration would be 2/3 ms. As this is identical to the duration found for Tx′, an optimal solution has been found and the iteration would be ceased at this point.

The result of this calculation may be a set of gradient waveforms for each transformed axis. If desired, these waveforms can be transformed back into logical or physical coordinate spaces using a rotation matrix approach similar to that described above.

In some embodiments, if the durations of the set of gradient waveforms on each transformed axis are equal to each other, then it may be determined that a minimum time solution has been found. However, if the gradient waveforms have different durations on any axis, then an improved solution may exist at a different rotation angle. To find this angle, a new selection of transform parameter can be selected, and the same procedure may be repeated until an acceptable solution is found. Once a minimum time solution has been found, the calculated waveforms in the transformed space may then be transformed back to the physical space to drive the MRI system's gradient hardware.

The required degree of rotation for the transformed space that may be searched for an optimal solution may be limited to only one quadrant of the circle (in the two-dimensional example, 0-90 degrees) shown in FIG. 4, or one eighth of the space of solid angles in the 3-dimensional case In some cases, the target function of differences between gradient durations may be well-behaved and smooth, meaning that a rapid nonlinear iterative solution solver can be applied. A binary search implementation can be made to find the best solution within at least about 1, 2, 3, 4, 5, 6, 7, 8, 9, 10, 20, 30, 40, 50, or 100 iterations. In some examples, a best solution may be found within at most about 1, 2, 3, 4, 5, 6, 7, 8, 9, 10, 15, 20, 30, 40, 50, 100, 200, 300, 400, 500, or 1000 iterations. In some cases, a nonlinear iterative search algorithm, such as conjugate gradient descent, Krylov subspace methods, and others can be used. Commonly used implementations can be found in MATLAB, C, C++, and other programming languages. A nonlinear iterative search algorithm may be suited for three-dimensional solutions, where the additional degree of freedom in the solution may render a binary search inefficient.

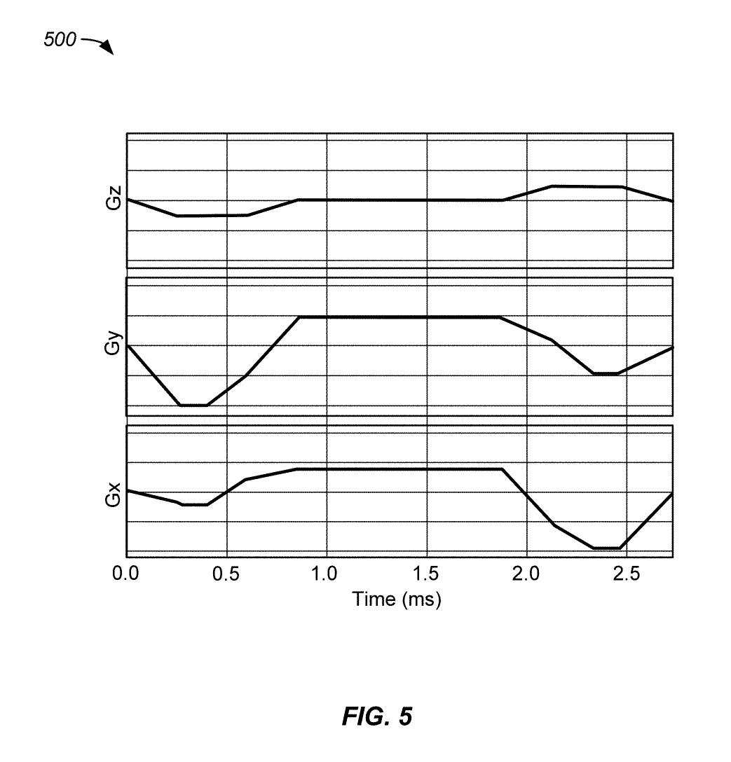

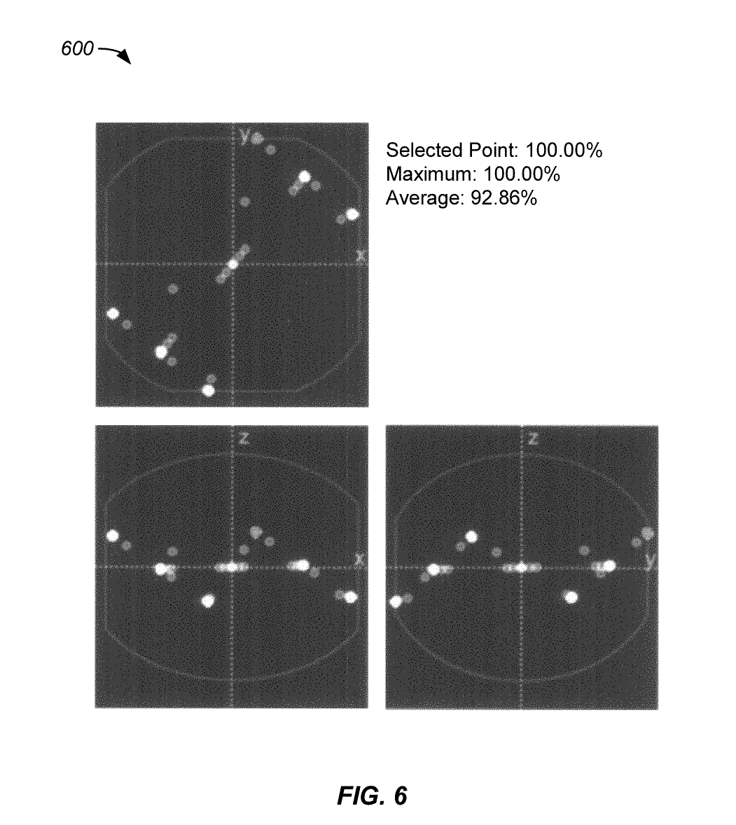

FIG. 5 shows the physical gradients designed by methods of the disclosure as a function of time, for a case in three-dimensions. FIG. 6 shows the point-wise gradient change limits for the waveform of FIG. 5. Most data points are at the theoretical limit, and the average data point is at about 93% of that limit. A truly optimal waveform would be at 100%. The methods described herein can therefore come very close to the theoretical ideal while taking very little time to calculate.

Methods and systems of the disclosure may be used for nonlinear magnetic field gradients, in which the constraint space may be more difficult to describe than the geometric shapes shown here.

Additional special constraints may be used depending on how the resulting gradient is expected to be used. For example, if the gradient must be freely rotatable so that it can be used in any scan-plane orientation, then constraints may be limited to a spherical space inscribed into the existing combined constraint. As previously discussed, it may be desirable for one or more of the gradient axes to be scaled down independently, in which case that scaling may result in exceeding limits on another axis. Use of either the proportional or magnitude/spheroidal optimization methods can avoid this difficulty. This may be of concern when designing gradients to be used in phase-encoding, unless separate optimizations are to be used for each phase-encoding operation.

This technique may converge quickly. In some examples, this technique may converge in a time period of at least about 1, 2, 3, 4, 6, 7, 8, 9, 10, 15, 20, 30, 40, 50, or 60 seconds or 1, 2, 3, 4, 5, 6, 7, 8, 9, 10, 15, 20, 30, 40, 50, or 60 minutes or 1, 2, 3, 4, 5, 6, 7, 8, 9, 10, 12, 18, or 24 hours. This technique may also not be computationally intensive and may also be sped up by further parallelization of the computation operations. In particular, multiple values of the transform parameter could be independently analyzed, effectively parallelizing operations 303 through 306 in FIG. 3. Parallelization may be particularly useful in a three-dimensional computation. A good initial estimation (or seed) for the transformation between the physical space and the transformed space may also greatly speed up the computation. This may be accomplished through heuristic algorithms based upon the gradient parameters to be optimized.

For example, if areas Ax′, Ay′, and Az′ are desired, an initial guess for slew rate limits and gradient limits along these axes might be a set of parameters that are scaled proportionally to the relative sizes of the desired areas:

$${SR}_{i} ∝ \frac{{A}_{i}}{\sqrt{{A}_{{x}^{′}} + {A}_{{y}^{′}} + {A}_{{z}^{′}}}}$$

Here, i represents each of x′, y′, and z′.

The technique described above may be further optimized by combining iterations for different types of transformations (e.g., rotative and proportional). In other words, both rotative and proportional solutions might be obtained, and the fastest of the two chosen for use. In this case, the additional optimizations may take very little time if the solution from the other transformation type is used as a starting point for the next type of iteration. Otherwise, the iteration may proceed as in the original case.

The ability to produce multidimensional optimized gradients with given start and end amplitudes, areas, and moments may also be incorporated into a graphical tool for MRI pulse-sequence designers (or systems) to rapidly and flexibly produce pulse sequences. Such a tool may be presented as a graphical user interface of the system. Such a tool may provide the ability to arbitrarily place pulse blocks with given amplitudes, areas, and moments, and to specify their temporal relationships to one another. In such a case, the ability to rapidly compute new optimized gradients may be essential to providing immediate feedback to the user in response to parameter changes.

In addition to peak slew rate limitations, alternative or additional gradient safety limits may be applied. For example, in the so-called “fixed-parameter” mode of MRI scanning for use on patients with indwelling metallic implants, additional constraints on peak gradient slew rate and root-mean-square (RMS) gradient slew rate may be applied. These additional constraints may be incorporated into the separable design process and similarly used to arrive at an efficient set of waveforms given the combination of all applied constraints. Similarly, these additional constraints could be applied on patients undergoing interventional procedures using metallic catheters, guidewires, and other interventional devices.

While the techniques of the disclosure may have greatest application in the design of waveforms by specified area, moments, and start and end amplitudes, there may also be the possibility of creating specific k-space trajectories via the same techniques. k-Space is the term for the format in which MRI raw data is initially collected. This raw data must undergo a Fourier transform in order to convert it to image data. Locations traversed in k-space are proportional to the net integrated area under the gradient waveforms; thus, specifying gradients by their net area can directly lead to traversal of a desired k-space trajectory. Sampling may be performed along simple trajectories that allow for a trivial solution and shorter scan times. For example, such k-space sampling may be along parallel lines.

More complicated sampling trajectories may be advantageous, but often may also require nontrivial solutions and, thus, longer scan times. For example, a spiral k-space trajectory, first proposed by both Likes (U.S. Pat. No. 4,307,343) and Ljunggren (JOURNAL OF MAGNETIC RESONANCE S4, 338-343 (1983)), can imply a specific area requirement for arriving at each k-space location. Spiral scans may be an efficient way to cover k-space and may be particularly advantageous in the presence of a dynamic environment such as in the heart or flowing blood.

There are a number of gradient waveforms that may trace out a particular spiral k-space trajectory. The design of these gradient waveforms may be an important element of spiral scanning, and a number of iterative and non-iterative approaches (e.g., U.S. Pat. No. 6,020,739) have been successfully applied to this problem. Again, however, these approaches may be time consuming to implement and not readily amenable to real-time imaging.

To arrive at a spiral trajectory in a time-efficient manner using the disclosed methods, the k-space sampling step may be set as finely as desired for accurate trajectory fidelity. Then, starting from the first k-space sample (e.g., at the k-space origin), separate optimization procedures may be used to step from the previous k-space location to the next locations. At each step, the start amplitude may be specified as the ending amplitude of the previous step, and the end amplitude may be left unconstrained. In the final step, a rewinder (the trajectory segment that connects the end of the spiral with the origin) may be designed with zero end amplitude and sufficient area to refocus to the k-space origin.

### Waveform Switching

MRI may require the rapid uploading of sets of arbitrary waveforms, that include waveforms for gradients, radiofrequency (RF) channels, shims, and/or fields into a piece of dedicated MR sequencing hardware that may be limited in processing power and/or available memory. Parameters of these waveforms such as their durations, amplitudes, data points, and number all may change arbitrarily and may not be known ahead of time.

While memory and computation power may be getting cheaper, sequencer hardware systems tend to be memory and processor-limited. For example, it may be impractical to provide enough on-board memory on these processors to contain all the samples needed to sequence an entire 2-hour scan with 5 16-bit data channels at 500 kHz (˜32 GB of memory). Even if the memory itself were not a limitation, the time required to transfer these amounts of data may prohibit real-time sequencing changes.

MR imaging sequences, though, may consist of a high degree of repetition. Therefore, vastly smaller chunks of waveform and associated parameter data may be uploaded to the sequencing hardware along with a schedule of instructions for the order and amount of repetition required for proper playback. This type of simple compression may reduce memory requirements, even for very long scans. Because of processing limitations, the method for compression may be through per-axis waveform schedulers, shown in conceptual form in FIG. 0.7.

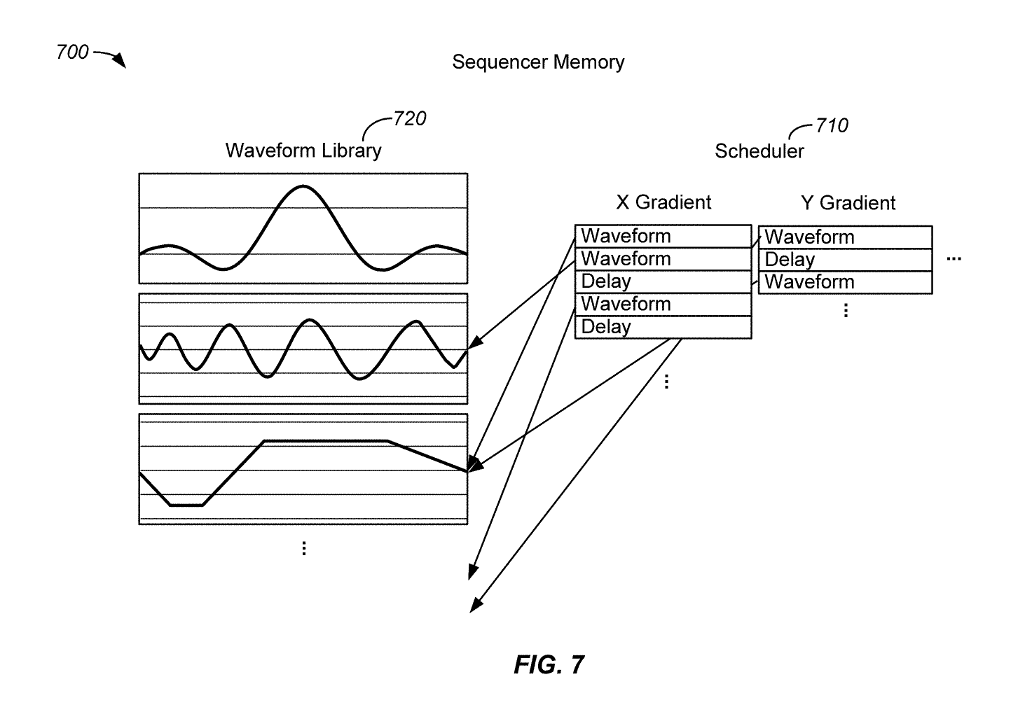

As shown in FIG. 7, uploaded schedulers 710 may be “played” for each waveform axis as a sequence is executed. The schedulers may provide a list of pointers to waveforms in the uploaded waveform library 710, so that waveform sections that may need to be repeated are only stored once. The scheduler may also: execute simple ‘transformations’ on any waveform in the library, including bulk amplitude changes, duration changes, phase/rotation changes; change the waveform pointer to point at a different location in the waveform library; or schedule delay elements.

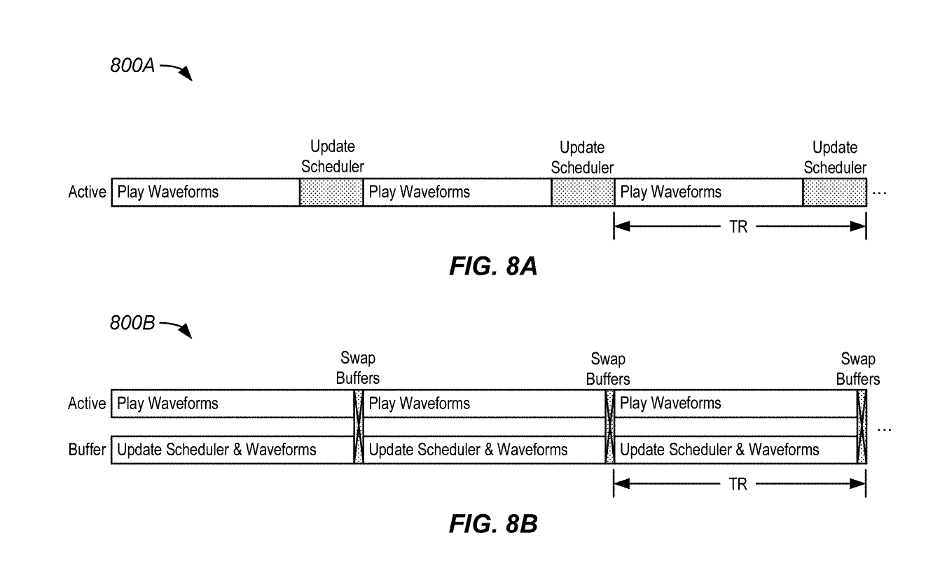

Serial sequencing 800A is shown in FIG. 8A. Each axis' scheduler may execute until it reaches the end of its sequence of instructions for playback. Additional time may then be reserved for updating the scheduler with any changes to the set of waveforms parameters. The complete cycle (playback+scheduler updating), occurs over a time interval TR and repeats itself with the updated scheduler being played at the start of the next cycle. This allows for basic MRI sequencing and may provide all the functions needed for scanning when all of the possible scan parameters are known in advance. Serial sequencing, as described herein, may be combined with or modified by U.S. Pat. Nos. 7,053,614, 7,102,349, and 5,465,361, which are entirely incorporated herein by reference.

The method of FIG. 8A may not be capable of addressing changing waveforms and sequence timings based upon arbitrary external events, such as changes entered via user input. In this case, it may be that no amount of change to the scheduler can provide the unanticipated new waveform that is needed—additional waveform uploading, and, thus, additional sequencing time may be required. Furthermore, the serial nature of the scheduler update after each playback period (FIG. 8A) indicates that scan efficiency may be compromised, as all sequencers may be inactive during scheduler updating. In order to keep TR to a minimum, the serial nature of sequencing may also limit the amount of scheduler changes that can practically be accomplished during each TR interval. To permit faster changes to arbitrary waveforms during active scanning, another method is needed.

This disclosure provides systems and methods 800B for buffering changes to the scheduler and waveform libraries while keeping the existing hardware structure and memory layout, as shown schematically in FIG. 8B. Additional memory may be allocated within the sequencer to permit buffering of all scheduler updates and associated waveforms. While one TR of waveforms is being played from an active memory region, the scheduler and waveform library for a future TR may be updated into the buffer memory.

At the end of one TR, the active memory region under playback may be swapped with the buffer memory region containing the next updates to be played. Depending on hardware limitations, this swap may require a short period of sequencer inactivity, or it may be possible to perform this swap atomically, in which case no period of sequencer inactivity is required. In the case of atomic swapping, then full-duty-cycle waveform playback may be achieved while allowing for arbitrary changes in sequences to be driven by the external host computer.

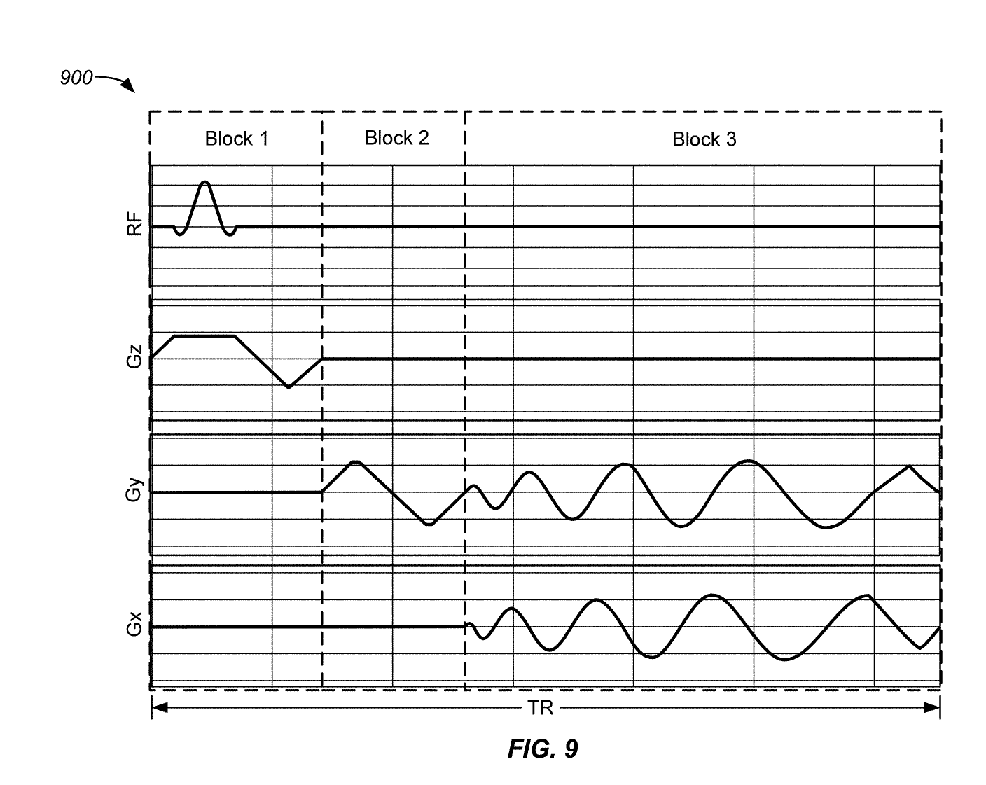

Each TR interval may be broken into one or more sub-intervals, called blocks to facilitate fast changes to waveforms. For example, FIG. 9 shows one TR 900 of a spiral flow-encoded pulse sequence wherein three logical functions are sequentially completed: slice selection, flow encoding, and spiral readout. These blocks may or may not be divided into separate sub-blocks (labeled Block 1, Block 2, and Block 3 here). Blocks may contain logical elements of the pulse sequence that include, but are not limited to, an inversion pulse or flow-encoding gradients. Moreover, several logical functions may be combined into one block. Real-time changes such as rotations, scaling, and enabling/disabling may be performed at the block level, allowing the pulse sequence designer the ability to precisely define the scope of any anticipated change.

While the present technique may allow for uploading and playback of arbitrary waveforms at any time, it may also be combined with one or more conventional methods (e.g., providing special functions for waveform scaling, rotations, phase modifications, etc.) to allow a more limited set of modifications at the sequencer level. This may permit backward compatibility with existing applications that may require such operations to be present on the sequencer. Moreover, it may also be more efficient to perform such waveform transformations without re-uploading the waveforms to the sequencer.

If the computer servicing the buffer memory is unable to achieve real-time response, then a longer buffer of queued TRs may be desired. The technique may be adapted to create a longer waveform and scheduler queue that permits the waveform-generating computer to have periodic intervals of slower responsiveness. If this buffer were implemented as a standard first-in-first-out (FIFO) queue, then any asynchronous changes to the sequence may be delayed by a time corresponding to the buffer's length. To prevent this latency, the buffer may be safely flushed whenever an unanticipated change occurs. Flushing the queue from the end and going backward may allow the fastest possible change while allowing for potential computer slowdowns.

As an example, during a spiral-scanning MRI experiment, the user may desire to acquire a higher resolution or a different field-of-view. Such alterations to the pulse sequence may necessitate a change to the spiral readout trajectory that may not have been anticipated prior to scanning. Other systems presently available may not permit changes to the waveform library after the start of a scan, and, thus, may not allow the required change to the spiral readout trajectory. These changes may be permitted, however, with architecture of the present invention as a buffer memory region exists for storing the waveforms needed to change the spiral readout trajectory prior to playback. In addition, such new waveforms may also have different lengths and other associated parameters, which may require updates to the scheduler which can also be generated in the buffer memory region prior to playback.

In another example, the present invention may allow an imaging sequence to autonomously adapt to conditions based upon image features of prior acquired real-time data. If prior real-time images indicate that the field-of-view is too small for the area being displayed, alternative spiral waveforms may be generated and substituted into the imaging sequence in real-time.

In yet another example, spiral trajectory corrections based upon eddy-current estimates may be pushed to the sequencer in real-time during scanning, rather than stopping the imaging sequence, making the corrections, and restarting.

The present invention may allow more time to be dedicated to scheduler and waveform updates, without increasing the total scan time and also may permit any sequence to be played as long as the respective update required for desired playback can be computed faster than TR. In addition, an interrupt or other standard concurrency technique (e.g., mutex, semaphore, etc.) may be used to adaptively set the sequence repetition time to accommodate whatever time is required to sequence the next interval by extending the current TR or by interjecting a transitional TR interval.

Moreover, the methods and systems disclosed herein may also allow all aspects of the sequence to be changed, including, but not limited to, the waveforms in the uploaded library, sequence timings, and number of waveform pulses.

Moreover, methods of the disclosure may be applied on any scanner (e.g., MRI scanner) that uses two-level scheduler and waveform libraries. At the present time, most scanners use such architecture as a part of their sequencing hardware.

### Late Gadolinium Enhancement

This disclosure provides systems and methods for three-dimensional (3D) volumetric late gadolinium enhancement (LGE) magnetic resonance imaging (MRI). Methods of the disclosure can provide for image acquisition from a subject with a limited number of breath holds, in some cases with a single breath hold, thereby aiding in minimizing discomfort to the subject and providing for improved spatial and temporal MRI.

In some examples, single breath-hold 3D volumetric LGE imaging sequences of the disclosure overcome the limitations of LGE methods currently available to characterize the entire left ventricle (LV) of a subject. LGE imaging methods of the present disclosure can obtain a single breath hold 3D volumetric scan of an LV of a subject in at most about 60, 50, 40, 30, 20, 15, 14, 13, 12, 11, or 10 heart beats of the subject. In some situations, this is achieved using time efficient 3D stack-of-spiral readout and state-of-art parallel imaging reconstruction.

In some cases, because of the ease of acquisition, the entire 3D dataset can be repeatedly acquired within a given time period (e.g., at least every 0.1 minutes, 0.5 minutes, 1 minute, 2 minutes, 3 minutes, 4 minutes, 5 minutes, 10 minutes, 20 minutes, 30 minutes, or 1 hour) to provide temporal characterization of early-to-late gadolinium enhancement (ELGE) phenomenon. We have demonstrated the feasibility of this method on patients with and without ischemic myocardial disease.

This disclosure provides rapid inversion recovery 3D imaging which allows entire LV coverage within 15, 14, 13, 12, 11, 10, or fewer heart beats using time-efficient spiral readout and a parallel imaging reconstruction method. This technique can be applied to time-resolved early-to-late Gadolinium enhancement imaging to capture contrast wash-out kinetics with 1 minute temporal resolution.

Gadolinium enhancement effects can vary spatially and temporally within the region of infarction. This may be due to the heterogeneous viability of infarct tissues and may provide another measure of myocardial tissue characteristic.

In some situations, methods of the disclosure provide for the imaging of heart tissue (e.g., heart muscle). Such methods are based, at least in part, on the unexpected realization that, by acquiring an incomplete data set within a cardiac cycle and during a single breath hold of the subject, the time for acquiring an image for a given region of interest can be substantially decreased, which enables the acquisition of other information that would otherwise not be attainable, such as kinetic information. The method may be repeated to obtain a complete data set required to generate a volumetric scan of the heart or a portion of the heart of the subject. For example, within each cardiac cycle up to 1%, 2%, 3%, 4%, 5%, 6%, 7%, 8%, 9%, 10%, 15%, 20%, 30%, 40%, 50%, 60%, 70%, 80%, 90%, or 95% of the complete data set may be acquired. The method of acquiring a scan can be repeated to generate a complete data set over, for example, at least 1, 2, 3, 4, 5, 6, 7, 8, 9, 10, 15, 20, 30, 40, 50, or 100 cardiac cycles. This can be implemented with the aid of non-Cartesian readouts.

### Methods for LGE Imaging

An aspect of the present disclosure provides methods for acquiring multi-dimensional volumetric LGE imaging sequences. The multi-dimensional volumetric LGE imaging sequences can be two-dimensional (2D), three-dimensional (3D), or more. In some cases, the multi-dimensional volumetric LGE can include a time dimension. A multi-dimensional volumetric image can be viewed as a function of time.

A method for acquiring 3D volumetric MRI with contrast enhancement during a breath-hold of less than 15 heart beats comprises administering a precursor of a contrast agent to a subject under diagnosis and/or treatment, and retrieving, with the aid of an MRI system, a time-efficient non-Cartesian readout from the subject. The precursor of the contrast agent can be ingested by or injected into the subject or administered to the subject intravenously. This method can be repeated as required in order to diagnose and/or treat the subject. For instance, this method can be repeated at least 1 time, 2 times, 3 times, 4 times, 5 times, 10 times, 20 times, 30 times, 40 times, 50 times or 60 times.

During the breath hold, a body of the subject or portion thereof (e.g., area of the subject being imaged) may be substantially immobile. In such a case, the body of the subject or portion thereof may not move laterally.

A single breath hold may include less than or equal to about 60, 50, 40, 30, 20, 19, 18, 17, 16, 15, 10, or 5 heart beats. A single breath hold can span a time period of at least about 5 seconds, 10 seconds, 11 seconds, 12 seconds, 13 seconds, 14 seconds, 15 seconds, 20 seconds, 30 seconds, 40 seconds, 50 seconds or 60 seconds.

In some situations, the time-efficient non-Cartesian readout comprises a stack-of-spirals or stack-of-EPI (echo planar imaging) or cone readout.

In some examples, providing the time time-efficient non-Cartesian readout can include employing parallel imaging reconstruction. Images can be acquired and reconstructed simultaneously or substantially simultaneously. As an alternative, images can be acquired and reconstructed sequentially—i.e., reconstruction followed by acquisition. In some situations, generalized auto-calibrating partially parallel acquisition (GRAPPA) and/or self-consistent parallel imaging reconstruction (SPIRiT) may be employed during image acquisition and/or reconstruction. In GRAPPA, data is acquired by fully sampling the center of k-space and sub-sampling the rest of k-space, and an image is reconstructed by utilizing coil sensitivity encoding through partial set of k-space. In SPIRiT, data is acquired in the same way as GRAPPA, but an image is reconstructed by utilizing coil sensitivity encoding through all k-space samples. GRAPPA and SPIRiT enable image reconstruction through partially acquired k-space data.

The time-efficient non-Cartesian readout can be acquired by employing massively parallel computation to reduce reconstruction time. This can entail parallel computing to reduce or minimize computation time. In some situations, parallel computing can include the use of a network in a distributed computing fashion (see below).

Parallel imaging can enable reduced scan time by partially acquiring k-space data. Further time efficiency can be achieved by compressed sensing, which is a technique to reconstruct an image from only partial set of k-space data by utilizing image sparsity. In some cases, this can further include employing massively parallel computation to reduce reconstruction time.

The contrast agent can comprise hyperpolarized chemical species or paramagnetic agents, or ferromagnetic agents. In some examples, the contrast agent comprises gadolinium.

Gadolinium is may be a water soluble, non-iodinated contrast substance that is distributed in extracellular fluid and may exhibit heightened ferric properties which enhance magnetic resonance imaging. Gadolinium may be employed safely as a contrast substance in other imaging applications, in some cases with there being only a 0.06% adverse reaction rate and a 0.0003% to 0.01% severe life-threatening allergic reaction rate to intravenous administration of gadolinium.

Gadolinium may be administered to the subject as a gadolinium chelate, such as, for example, gadopentate dimeglumine, gadodiamide, gadoteridol and gadoversetamide. Gadolinium chelates may exhibit similar pharmacologic characteristics and may not be differentiable on the basis of adverse reactions.

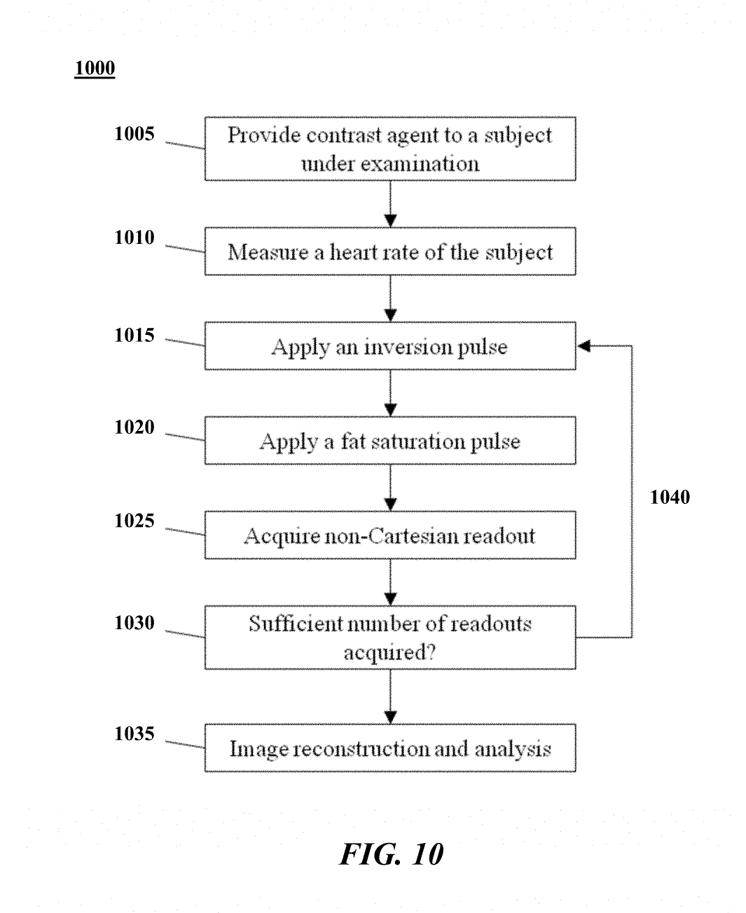

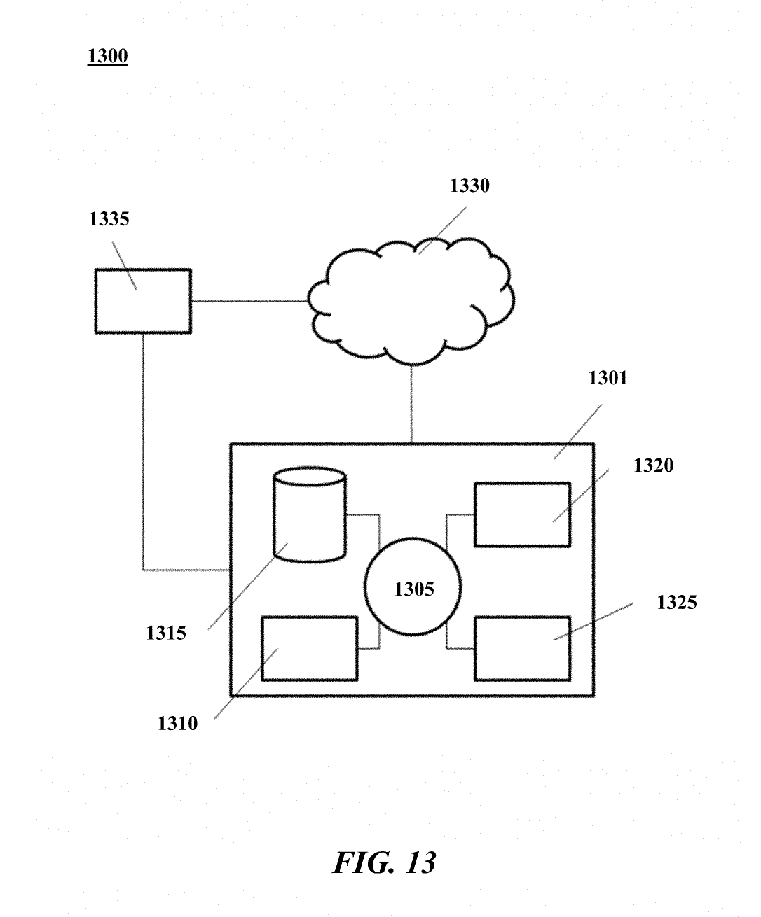

FIG. 10 shows an ELGE method 1000 of the present disclosure. The method 1000 can be applied to a subject undergoing diagnosis and/or treatment for subject suspected of exhibiting an observable manifestation of a disease or an adverse health condition, such as myocardial infraction. The method 1000 can be implemented with the aid of a computer system (e.g., the computer system 1301 of FIG. 13) that is programmed or otherwise configured to facilitate one or more operations of the method 1000, such as directing the application of radiofrequency (RF) pulses, acquiring readouts, and performing data processing and/or analysis.

With reference to FIG. 10, in a first operation 1005, a precursor of a contrast agent can be provided to the subject. The contrast agent can be gadolinium, which can be administered to the subject with the aid of a gadolinium chelate precursor, such as, for example, gadopentate dimeglumine, gadodiamide, gadoteridol and gadoversetamide. Once administered to the subject, the precursor yields the contrast agent in the body of portion of the body of the subject. The precursor can be administered at least about 1 minute (“min”), 2 min, 3 min, 4 min, 5 min, 10 min, 20 min, 30 min, 40 min, 50 min, 1 hour, 2 hours, 3 hours or 4 hours prior to the subsequent operation of the method 1000.

Next, in a second operation 1010, a heart rate of the subject is obtained. The heart rate of the subject can be obtained with the aid of a non-invasive technique, such as, for example, electrocardiography (EKG), which can generate an electrocardiogram. The electrocardiogram can show individual heart beats as a function of time.

Next, in a third operation 1015, the computer system directs the application of a first RF pulse to an area of the body of the subject under interrogation (e.g., area adjacent to the heart of the subject). The first RF pulse can be applied during a single breath hold of the subject. In such a case, the subject is requested to hold a breath of the subject. The first RF pulse can be an inversion pulse. The inversion pulse can have parameters that are selected to robustly cancel MR signals from select tissues. An inversion pulse can enable the cancellation of a signal from material with a given T1 relaxation time. The inversion pulse can be used to null out MR signals from a tissue or organ under interrogation, such as, for example, the heart. The inversion pulse can be used to reduce or eliminate (e.g., cancel out) a signal from a portion of the tissue or organ under interrogation that does not have a contrast agent. The inversion pulse can be used to reduce or eliminate MR signals from a static heart muscle, and reduce or eliminate MR signals from unwanted tissue (e.g., normal tissue). The inversion pulse can reduce or eliminate any MR signals that may be detected from the area of the body of the subject (e.g., heart muscle) that does not interact with (e.g., absorb) the contrast agent, thereby reducing or eliminating static signals from the area of the body of the subject. In some situations, the inversion pulse can be used to reduce or eliminate MR signals from unwanted areas of the body of the subject, such as, for example, fat tissue.

The inversion pulse can be applied within about 1 millisecond (“ms”), 10 ms, 20 ms, 30 ms, 40 ms, 50 ms, 100 ms, 200 ms, 300 ms, 400 ms, 500 ms, 1 second (“s”), 2 s, 3 s, 4 s, 5 s, or 10 s of a heart beat of the subject, as can be determined in the second operation 1010. The inversion pulse can have a duration from about 0.1 ms to 50 ms, or 1 ms to 10 ms. The inversion pulse can be a 180° inversion pulse.

As an alternative or in addition to the inversion pulse, a velocity saturation pulse and/or an adiabatic pulse can be employed in the third operation 1015. Pulses employed herein can be as described in, for example, M A Bernstein, K F King and X J Zhou, “Handbook of MRI pulse sequences,” Burlington, Mass., Elsevier Academic Press (2004) and R H Hashemi, W G Bradley, C J Lisanti, “MRI: the basics,” Philadelphia, Pa., Lippincott Williams & Wilkins (2004), each of which is entirely incorporated herein by reference. Next, in a fourth operation 1020, the computer system directs the application of a second RF pulse to the area of the body of the subject under interrogation. The second RF pulse can be a fat saturation RF pulse (“also “fat saturation pulse” herein). In the fat saturation pulse, chemical frequency differences can be used to reduce or eliminate MR signals from fat tissue on or around the area of the body of the subject under interrogation (e.g., heart). The fat saturation pulse can have a frequency that is selected to reduce or eliminate MR signals from fat tissue. The fat saturation pulse can be applied within about 1 millisecond (“ms”), 10 ms, 20 ms, 30 ms, 40 ms, 50 ms, 100 ms, 200 ms, 300 ms, 400 ms, 500 ms, 1 second (“s”), 2 s, 3 s, 4 s, 5 s, or 10 s upon applying the inversion pulse in the third operation 1015. In some cases, the fat saturation pulse can be precluded.

Next, in a fifth operation 1025, the computer system can acquire a non-Cartesian readout from the area of the body of the subject under interrogation. The non-Cartesian readout can be acquired following the fat saturation pulse in the fourth operation 1020. The non-Cartesian readout can be acquired within about 1 millisecond (“ms”), 10 ms, 20 ms, 30 ms, 40 ms, 50 ms, 100 ms, 200 ms, 300 ms, 400 ms, 500 ms, 1 second (“s”), 2 s, 3 s, 4 s, 5 s, or 10 s upon applying the inversion pulse in the third operation 1015. The non-Cartesian readout can be acquired within about 0.01 ms, 0.1 ms, 1 ms, or 10 ms upon applying the fat saturation pulse in the fourth operation 1020. In some cases, the non-Cartesian readout is acquired immediately following the fat saturation pulse. As an alternative, the non-Cartesian readout can be acquired immediately following the inversion pulse (and the fat saturation pulse can be precluded).

Acquisition of the non-Cartesian readout can comprise acquiring one or more k-space trajectories. A k-space trajectory can be non-Cartesian. In some examples, the trajectory is in the form of a spiral, a cone, a cylinder, or a propeller. For instance, the trajectory can be taken along the surface of a cone, cylinder or propeller. In some situations, the non-Cartesian readout can be acquired at mid-diastole of the heart of the subject.

Magnetic resonance (MR) RF signals can be frequency modulated (FM). In a non-Cartesian readout, the frequency can be modulated to yield a k-space trajectory that is non-Cartesian. The non-Cartesian readout can comprise a readout that comprises a stack of spirals or readouts along a surface of a cone (e.g., when multiple spirals are obtained at varying points in time).

In cases in which the heart of the subject is under interrogation, the non-Cartesian readout can be acquired during diastole. In some situations, the non-Cartesian readout from the heart of the subject can be acquired during mid-diastole. The timing can be established by measuring a heart rate of the subject in the second operation 1010, which can enable the system to determine when to obtain the non-Cartesian readout such that the readout coincides with mid-diastole.

The readout (e.g., non-Cartesian readout) can be acquired from at least some or all of the area of the body of the subject being interrogated. In some examples, the readout can be obtained from at least some or all of the heart of the subject. In an example, the readout is obtained from substantially all of the heart of the subject (e.g., including heart muscle). This advantageously enables the acquisition of a readout from the heart of the subject within a single heart beat.

Next, in a sixth operation 1030, the computer system determines if a sufficient number of readouts have been acquired from the area of the body of the subject. In some cases, if at least 1, 2, 3, 4, 5, 6, 7, 8, 9, 10, 11, 12, 13, 14, 15, 20, 30, 40, or 50 readouts have been acquired from the area of the body of the subject or if a sufficient amount of time (e.g., at least about 1 second, 2 seconds, 3 seconds, 4 seconds, 5 seconds, 6 seconds, 7 seconds, 8 seconds, 9 seconds, 10 seconds, 11 seconds, 12 seconds, 13 seconds, 14 seconds, 15 seconds, 20 seconds, 30 seconds, 40 seconds, 50 seconds, 1 minute, 2 minutes, 3 minutes, 4 minutes, 5 minutes, or 10 minutes) has elapsed since the first pulse was applied to the body of the subject, then in seventh operation 1035 the computer system performs data processing and, in some cases, data analysis. Data processing can include image reconstructions, which can include generalized auto-calibrating partially parallel acquisition (GRAPPA), self-consistent parallel imaging reconstruction (SPIRiT), or both. In some examples, only SPIRiT is employed during the seventh operation 1035.

However, if in the sixth operation 1030 the computer system determines that a sufficient number of readouts have not been acquired, the operations 1015-1030 can be repeated 1040. The operations 1015-1030 can be repeated 1040 at least 1, 2, 3, 4, 5, 6, 7, 8, 9, 10, 11, 12, 13, 14, 15, 20, 30, 40, 50, or 100 times. In some cases, the operations 1015-1030 can be repeated 1040 during a single breath-hold of the subject.

Operations 1015-1030 can be performed following a single heart beat of the subject. Within 12 heart beats, for instance, operations 1015-1030 can be performed 12 times.

In some situations, operations 1015-1030 can be performed and repeated 1040 at a given time point or within a given time period upon providing the precursor of the contrast agent to the subject to acquire a first set of data. The first set of data can be acquired in a single breath-hold of the subject. The operations 1015-1030 can be performed and repeated 1040 during one or more subsequent breath-holds of the subject and at subsequent points in time to acquire additional sets of data.

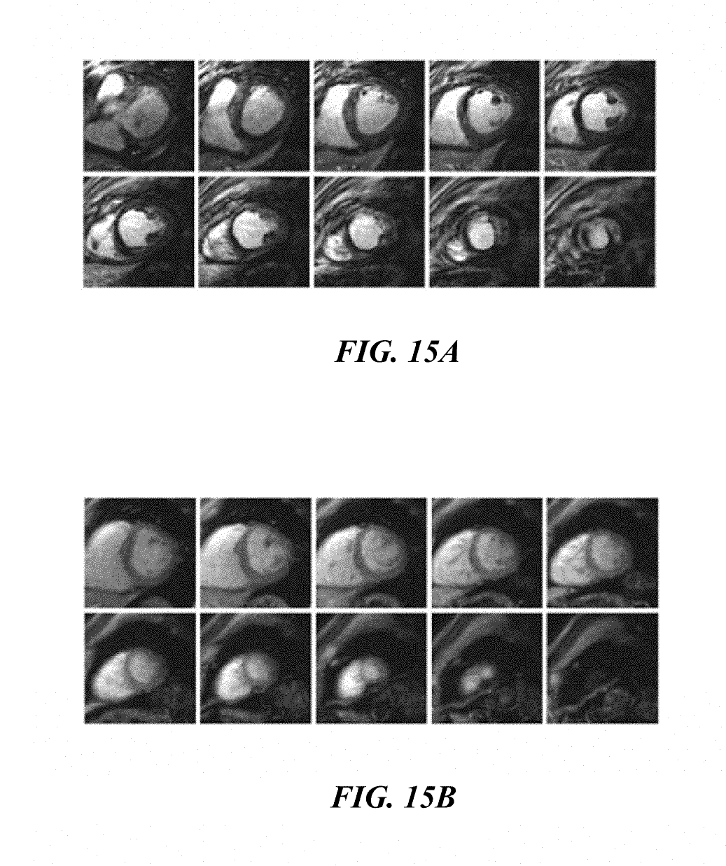

Following the seventh operation 1035, a reconstructed image can be presented to the subject. The reconstructed image can be presented to the subject on an electronic device that is communicatively coupled to the computer system (see, e.g., FIG. 15).

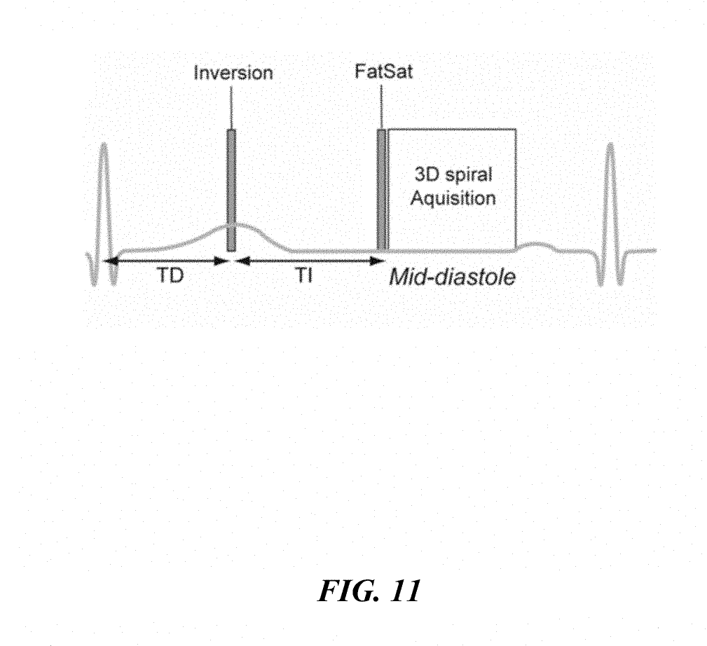

FIG. 11 schematically illustrates an ELGE method of the present disclosure. The ELGE method of FIG. 11 shows various operations of the method 1000 of FIG. 10. A series of RF pulses are shown in the figure that are situated in-between heart beats of the subject, as may be determined, for example, with the aid of EKG. The pulse sequence of FIG. 11 employs short inversion-time inversion recovery, which can employ a 180° inversion pulse to invert all magnetization. Then imaging proceeds after a delay (TI), when the longitudinal recovery of fat magnetization has reached the null point, when there is no fat magnetization to flip into an x-y plane. Tissues with a T1 relaxation time different to fat can have a non-zero signal, in some cases because they have not yet reached the null point, or have recovered beyond the null point. At least some tissues may recover more slowly than fat, and so a short inversion-time recovery images can have intrinsically lower signal to noise (SNR). In some situations, in interpreting the contrast between tissues, care may be taken due to the incomplete relaxation of the water signal of tissues when the image is acquired.

With continued reference to FIG. 11, the inversion pulse is applied following the preparation of an inversion magnetization for the inversion pulse. Following the inversion pulse and after an inversion delay time (TI), segmented 3D spiral acquisition can occur at mid-diastole.

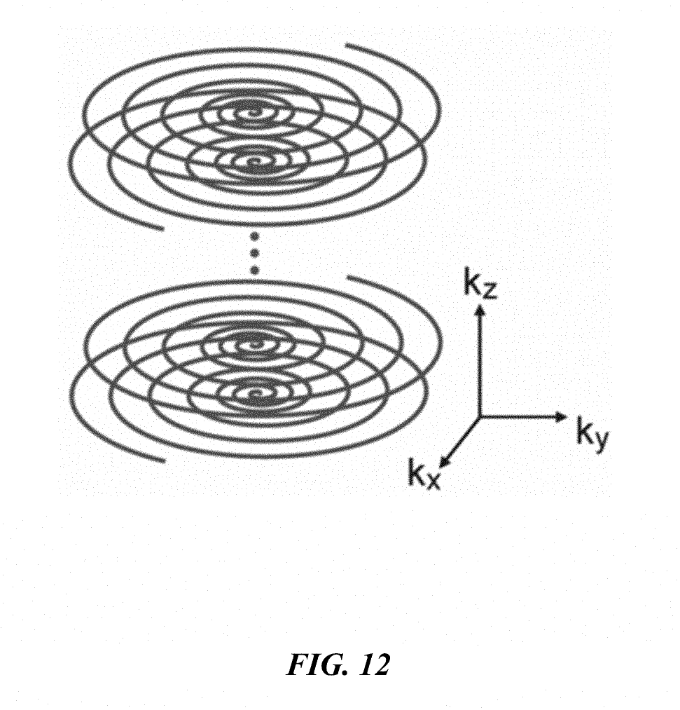

After the TI delay, a group of k-space trajectories can be obtained. In some examples, the trajectories are non-Cartesian. For example, the trajectories can be spiral, cones, cylinders, or propellers. In the illustrated example of FIG. 11, a stack of spiral k-space trajectories for 3D data acquisition are obtained, as shown in FIG. 12. FIG. 12 shows a plurality of spiral k-space trajectories, each of which may be obtained per individual 3D spiral acquisition. Per each k_{z} level, an inner part of spiral can be fully sampled and an outer part of the spiral can be two-fold under-sampled. The under-sampled 3D data can be reconstructed with the aid of an iterative self-consistent parallel imaging reconstruction (SPIRiT) approach. See, e.g., Lustig M, Pauly J M. Spirit: Iterative self-consistent parallel imaging reconstruction from arbitrary k-space. Magn Reson Med. 2010; 64:457-471, which is entirely incorporated herein by reference.

The pulse sequence of FIG. 11 can include an inversion preparation pulse followed by an inversion delay time (TI), a spectral selective fat saturation pulse, and the acquisition of 3D stack-of-spiral data, which may be acquired at mid-diastole. The spiral trajectory can be used in place of a 2D Fourier Transform (FT) readout employed in some conventional systems. This may be achieved using, for example, dual density sampling such that the inner part of k-space is fully sampled, and the remaining outer part is under-sampled by a factor of at least about 1.1, 1.2, 1.3, 1.4, 1.5, 1.6. 1.7, 1.8, 1.9, 2, 3, 4, 5, 6, 7, 8, 9, or 10. The data acquisition can then be segmented over at least 1, 2, 3, 4, 5, 6, 7, 8, 9, 10, 15, 20, 30, 40, 50, or 100 cardiac cycles by acquiring at least 1, 2, 3, 4, 5, 6, 7, 8, 9, or 10 spiral interleaves per each cardiac cycle. In an example, the remaining outer part is under-sampled by a factor of about 2, and the data acquisition is segmented over 10 cardiac cycles by acquiring 6 spiral interleaves per each cardiac cycle.

For readout excitation, either conventional slice selective radiofrequency (RF) pulse or spectral spatial RF pulse for further reduction of fat signal can be used. A low resolution field map can be acquired using at least two separate (and in some cases different) echo times with the inversion pulse turned off at the first cardiac cycle. The map can be used for linear off-resonance correction. The data from the second cardiac cycle with the first inversion preparation can be discarded.

In an example, a total scan time is about 12 heart beats of the subject being diagnosed and/or treated. The imaging parameters include inversion delay time=200 milliseconds (ms) to 300 ms, spatial resolution=1.7×1.7×7 mm³, field of view (FOV)=38×38×9.8 cm³, 14 partition slices, flip angle=25°, TR=11.8 ms, data acquisition time per heart beat=190 ms. Assuming a subject has about 60 heart beats per minute (or one heart beat per second), then in the period of about 12 seconds this yields about 24 to 30 scans. Each scan can yield a non-Cartesian (e.g., spiral) trajectory in k-space. Upon completion of the scans, a stack non-Cartesian trajectories (e.g., stack of spirals) in k-space can be generated for subsequent use in image reconstruction.

FIG. 11 shows pulses applied to the subject and data acquired from the subject in a single cardiac cycle (e.g., heart beat to heart beat) during a single breath hold of the subject. During the single cardiac cycle, non-Cartesian data can be acquired which can correspond to an incomplete data set for generating an image (e.g., three-dimensional image) of at least a portion of the body of the subject, such as a region of interest (ROI). For example, the data acquired during a single cardiac cycle can represent up to about 1%, 2%, 3%, 4%, 5%, 6%, 7%, 8%, 9%, 10%, 15%, 20%, 30%, 40%, 50%, 60%, 70%, 80%, 90%, or 95% of the complete data set for generating an image of at least a portion of the body of the subject. The complete data set can include all of the non-Cartesian data that is necessary to generate an image (e.g., three-dimensional image) of at least a portion of the body of the subject. The method of FIG. 11 can be repeated to acquire the complete data set to generate the image. For instance, the method of FIG. 11 can be repeated at least 1, 2, 3, 4, 5, 6, 7, 8, 9, 10, 15, 20, 30, 40, 50, or 100 times. Each repetition can fall within a cardiac cycle of the subject. Data acquisition can be coupled with data processing, as described elsewhere herein.

Methods for acquiring a volumetric scan of at least a portion of a body of a subject, such as the method of FIGS. 10 and 11, can be used to obtain a three-dimensional image of the heart of the subject at a single post-injection time or time interval, such as, for example, one minute after administration of a precursor of a contrast agent. Such methods can be repeated every 1 minute (min), 2 min, 3 min, 4 min, 5 min, 10 min, 15 min, 20 min, or 30 min following the administration of the precursor of the contrast agent (also “post-injection time” herein). Such repetition may require multiple breath-holds of the subject, in some cases one breath-hold per one repetition at a different post-injection time.

The methods of FIGS. 10 and 11 can be used to measure temporal variation of contrast enhancement in every locations of the image (e.g., three-dimensional image). For example, at a single post-injection time point (e.g., 1 minute), an image of a heart of the subject may be generated. The image can be generated by acquiring data in the manner provided in FIGS. 10 and 11 within a single breath hold. Additional images can be generated at subsequent post-injection time points (e.g., 2 minutes post-injection to 15 minutes post-injection, with an image generated every one minute). As an alternative, data at each post-injection time interval can be acquired and used to generate an image for the post-injection time interval at a subsequent point in time. The repetitions may require multiple breath-holds of the subject, with one breath-hold per one repetition at different post-injection time.

In an example, within one minute after the injection of a precursor of a contrast agent, a first set of data points is acquired from the heart of a subject during a first breath-hold of the subject. The data points can be maintained (or stored) in the memory location (e.g., database) of a computer system (see below). An individual data point can be non-Cartesian. The first set of data points includes ten individual data points, with each data point acquired according to the methods of the disclosure (e.g., the methods of FIGS. 10 and 11). That is, each data point in the first set can be obtained within individual heart beats of the subject during the single breath-hold. Each data point in the first set may not provide information that by itself is sufficient to generate an image of the heart of the subject, but the ten individual data points collectively may provide a complete data set that can be used to generate an image of the heart of the subject—i.e., the information of the ten data points may be collectively sufficient to generate an image of the heart of the subject. Thus, each data point in the first set can represent 10% of the information necessary to generate a complete image of the heart of the subject.

Next, at two minutes after injection of the precursor of the contrast agent, a second set of data points can be acquired from the subject during a second breath-hold of the subject. The second set of data points can include ten individual data points, with each data point acquired according to the methods of the disclosure (e.g., the methods of FIGS. 10 and 11). Such an approach can be repeated to generate additional sets of data points at subsequent post-injection time points and during subsequent breath-holds of the subject. For instance, a third set of data points can be obtained at three minutes after injection of the precursor of the contrast agent and at a third breath-hold of the subject, a fourth set of data points can be obtained at four minutes after injection of the precursor of the contrast agent and at a fourth breath-hold of the subject, and so on. This can be repeated, for example, every 1 min until at least 15 min, 20 min, or 30 min after injection of the precursor of the contrast agent. Each period to acquire a set of data points may require that the subject take a breath and maintain a breath-hold until the ten data points of a set of data points have been acquired.

The data in each set of data points can be used to generate an image of the heart of the subject. The image can be generated following the point in time in which each set of data is acquired, or after some or all sets of data has been acquired. Such an approach can aid in measuring the temporal variation of contrast enhancement in every locations of an image of the heart of the subject.

In some embodiments, a given sequencing interval can be broken into one or more sub-intervals, or blocks, to facilitate fast changes to waveforms. In the series of spiral trajectories of FIG. 12, three logical functions can be sequentially completed: slice selection, flow encoding, and spiral readout. These blocks may or may not be divided into separate sub-blocks. Blocks may contain logical elements of the pulse sequence that include, but are not limited to, an inversion pulse or flow-encoding gradients. Moreover, several logical functions may be combined into one block. Real-time changes, such as rotations, scaling, and enabling/disabling, may be performed at the block level, allowing the pulse sequence designer the ability to precisely define the scope of any anticipated change.

### Systems

This disclosure provides computer system that may be programmed or otherwise configured to implement methods provided herein.

FIG. 13 schematically illustrates a system 1300 comprising a computer server (“server”) 1301 that is programmed to implement methods described herein. The server 1301 may be referred to as a “computer system.” The server 1301 includes a central processing unit (CPU, also “processor” and “computer processor” herein) 1305, which can be a single core or multi core processor, or a plurality of processors for parallel processing. The server 1301 also includes memory 1310 (e.g., random-access memory, read-only memory, flash memory), electronic storage unit 1315 (e.g., hard disk), communications interface 1320 (e.g., network adapter) for communicating with one or more other systems, and peripheral devices 1325, such as cache, other memory, data storage and/or electronic display adapters. The memory 1310, storage unit 1315, interface 1320 and peripheral devices 1325 are in communication with the CPU 1305 through a communications bus (solid lines), such as a motherboard. The storage unit 1315 can be a data storage unit (or data repository) for storing data. The server 1301 is operatively coupled to a computer network (“network”) 1330 with the aid of the communications interface 1320. The network 1330 can be the Internet, an internet and/or extranet, or an intranet and/or extranet that is in communication with the Internet. The network 1330 in some cases is a telecommunication and/or data network. The network 1330 can include one or more computer servers, which can enable distributed computing, such as cloud computing. The network 1330 in some cases, with the aid of the server 1301, can implement a peer-to-peer network, which may enable devices coupled to the server 1301 to behave as a client or a server. The server 1301 is in communication with a imaging device 1335, such as a magnetic resonance imaging (MRI) device or system. The server 1301 can be in communication with the imaging device 1335 through the network 1330 or, as an alternative, by direct communication with the imaging device 1335.

The storage unit 1315 can store files, such as computer readable files (e.g., MRI files). The server 1301 in some cases can include one or more additional data storage units that are external to the server 1301, such as located on a remote server that is in communication with the server 1301 through an intranet or the Internet.

In some situations the system 1300 includes a single server 1301. In other situations, the system 1300 includes multiple servers in communication with one another through an intranet and/or the Internet.

Methods as described herein can be implemented by way of machine (or computer processor) executable code (or software) stored on an electronic storage location of the server 1301, such as, for example, on the memory 1310 or electronic storage unit 1315. During use, the code can be executed by the processor 1305. In some cases, the code can be retrieved from the storage unit 1315 and stored on the memory 1310 for ready access by the processor 1305. In some situations, the electronic storage unit 1315 can be precluded, and machine-executable instructions are stored on memory 1310. Alternatively, the code can be executed on a remote computer system.

The code can be pre-compiled and configured for use with a machine have a processer adapted to execute the code, or can be compiled during runtime. The code can be supplied in a programming language that can be selected to enable the code to execute in a pre-compiled or as-compiled fashion.

Aspects of the systems and methods provided herein, such as the server 1301, can be embodied in programming. Various aspects of the technology may be thought of as “products” or “articles of manufacture” typically in the form of machine (or processor) executable code and/or associated data that is carried on or embodied in a type of machine readable medium. Machine-executable code can be stored on an electronic storage unit, such memory (e.g., read-only memory, random-access memory, flash memory) or a hard disk. “Storage” type media can include any or all of the tangible memory of the computers, processors or the like, or associated modules thereof, such as various semiconductor memories, tape drives, disk drives and the like, which may provide non-transitory storage at any time for the software programming. All or portions of the software may at times be communicated through the Internet or various other telecommunication networks. Such communications, for example, may enable loading of the software from one computer or processor into another, for example, from a management server or host computer into the computer platform of an application server. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links or the like, also may be considered as media bearing the software. As used herein, unless restricted to non-transitory, tangible “storage” media, terms such as computer or machine “readable medium” refer to any medium that participates in providing instructions to a processor for execution.

Hence, a machine readable medium, such as computer-executable code, may take many forms, including but not limited to, a tangible storage medium, a carrier wave medium or physical transmission medium. Non-volatile storage media include, for example, optical or magnetic disks, such as any of the storage devices in any computer(s) or the like, such as may be used to implement the databases, etc. shown in the drawings. Volatile storage media include dynamic memory, such as main memory of such a computer platform. Tangible transmission media include coaxial cables; copper wire and fiber optics, including the wires that comprise a bus within a computer system. Carrier-wave transmission media may take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CD-ROM, DVD or DVD-ROM, any other optical medium, punch cards paper tape, any other physical storage medium with patterns of holes, a RAM, a ROM, a PROM and EPROM, a FLASH-EPROM, any other memory chip or cartridge, a carrier wave transporting data or instructions, cables or links transporting such a carrier wave, or any other medium from which a computer may read programming code and/or data. Many of these forms of computer readable media may be involved in carrying one or more sequences of one or more instructions to a processor for execution.

The server 1301 can be configured for data mining, extract, transform and load (ETL), or spidering (including Web Spidering where the system retrieves data from remote systems over a network and access an Application Programmer Interface or parses the resulting markup) operations, which may permit the system to load information from a raw data source (or mined data) into a data warehouse. The data warehouse may be configured for use with a business intelligence system (e.g., Microstrategy®, Business Objects®).

The results of methods of the disclosure can be displayed to a user on a user interface (UI), such as a graphical user interface (GUI), of an electronic device of a user, such as, for example, a healthcare provider. The UI, such as GUI, can be provided on a display of an electronic device of the user. For example, an image of at least a portion of a body part of a subject under treatment and/or diagnosis may be reconstructed from k-space data and presented to the subject on a UI (e.g., GUI) of an electronic device of the subject, or a healthcare provider of the subject. The display can be a capacitive or resistive touch display. Such displays can be used with other systems and methods of the disclosure.

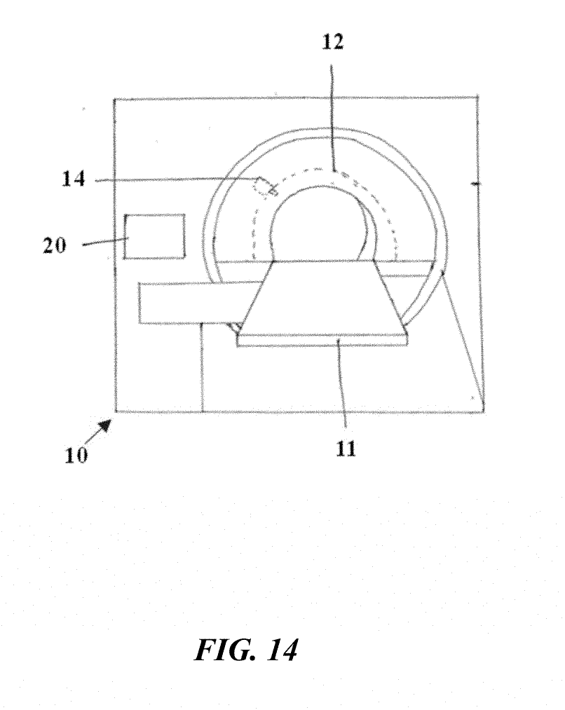

FIG. 14 shows a scanner 10 that is configured to implement the methods of the present disclosure. Various features of the scanner 10 may be as described in WO/2004/042656, which is entirely incorporated herein by reference. The scanner of FIG. 14 may be the imaging device 1335 of FIG. 13. In this example, the scanner 10 is a magnetic resonance (MR) scanner. However, it will be appreciated that any suitable scanner can be used. The MR scanner 10 includes a table 11 for a subject to lie on, a ring magnet 12, for example a super-conducting magnet, which extends around the patient table 11 and provides a constant magnetic field and a radio frequency (RF) source 14 for generating pulses (or RF pulses) that can be specific to hydrogen. The scanner 10 is operable to direct RF pulses towards the areas of the body of the subject that are to be examined. The RF pulses cause any protons in that area to absorb energy, which causes the protons to change their direction of spin and rotate at a particular frequency. Also included in the scanner are gradient magnets (not shown) that can be turned on and off very quickly in a specific manner, thereby to alter the main magnetic field on a very local level. Thus, an area of particular interest can be targeted and imaged in slices. A detector coil (not shown) is also provided for detecting changes in the magnetic field and sending that information to a computer system 20. The computer system can be the server 1301 of FIG. 13.

Included in the computer system 20 is computer software that is adapted to receive image data from the scanner 10, process that data and use it to construct an image. The software can be adapted to implement self-consistent parallel imaging reconstruction.

In use, the main magnet 12 is on, an RF pulse is applied and the gradient magnets are used to pick out a particular slice of the subject, for example a slice of the subject's heart. This causes any protons in the slice of interest to change their spin direction and frequency. Once this is done, and the RF pulse is removed, the protons slowly return to their natural alignment within the magnetic field and release their excess energy. This excess energy is detected by the detector coil 18, which produces a signal and sends it to a computer system, which constructs a suitable image and displays it on the screen. By varying the gradient magnets, a series of images taken as slices across, for example, a subject's heart can be obtained.

The software that is included in the computer system 20 can be configured to implement an improved image processing method, for example, starting with capturing a series of n images of a particular slice of the heart of a subject over a defined part of a heart beat cycle. Once this is done, a late enhanced image of the same slice can be captured over a portion of a heart beat cycle. This is typically taken over a quiescent part of the cycle. A reference frame or image can then be created. This can be done by selecting one of the captured images or alternatively by averaging all or at least a subset of the n images captured over a corresponding portion of the heart beat cycle to create the reference.

Once this is done, a plurality of disparity images can be calculated and saved, each disparity image representing a difference between one of the n captured images and the reference image.

The images can be processed to generate a profile of a particular region of interest (ROI) as a function of time. The profile of the ROI can be generated, for example, by plotting the intensity of the image at a given ROI against time.

The change in intensity of an image in an ROI can be indicative of the presence of absence of healthy or diseased tissue. The contrast wash out kinetics for normal and scarred tissue can be different, enabling the determination of the type of tissue (i.e., healthy or unhealthy) based on the kinetic profile of the tissue. In some cases, depending on the region of a body of a subject being imaged with Mill, the MR signal intensity of a given ROI can increase or decrease over time for scarred tissue. In some examples, if the heart of a subject is being imaged, the signal intensity for scarred tissue can increase over time, but the signal intensity for normal tissue can decrease over time. Such behavior can aid in determining whether a given region of a body of a subject (e.g., tissue) is healthy or unhealthy (e.g., scarred).

Methods of the present disclosure can enable the acquisition of MR images over time for a given region of interest within a relatively short time frame as compared to other methods currently available. This can advantageously enable the near real time assessment of the kinetics associated with the interaction between a contrast agent administered to a subject under interrogation and tissue with a region of interest (e.g., heart) of the subject. For instance, the change in intensity of MR images associated with a given ROI can, in nearly real time, enable the assessment of the kinetics associated with the interaction between a contrast agent and the tissue within the ROI. The kinetics can then be used to determine whether the tissue is healthy or unhealthy.

In some cases, the intensity of MR signals associated with a given ROI can be used to generate a trajectory of intensity over time. The trajectory can be used to calculate a rate of change of the intensity over time (or velocity), which can enable the determination of the state of the tissue being imaged (i.e., healthy or unhealthy). For example, in a plot of MR intensity as a function of time, scarred heart tissue can have a positive velocity (intensity increases with time) and normal heart tissue can have a negative velocity (intensity decreases with time).

Methods of the present disclosure can enable substantially rapid parallel imaging and/or processing, such as at an acquisition rate that is sufficient to acquire an entire data set in a single breath hold of a subject. With the aid of systems and methods provided herein, the dynamics of contrast enhancement in disease tissue can be captured.

### EXAMPLES

### Example 1: Scan Protocol

The time-resolved 3D ELGE imaging is performed on a General Electric® 1.5 Tesla scanner with 40 mT/m gradient amplitude and 150 T/m/s gradient slew rate, using an eight-channel cardiac coil array for signal reception. Cardiac MRI is obtained from consecutive subjects.

Contrast media (0.2 mmol/kg, gadoteridol) is injected into each subject at a rate of 2 ml/s followed by 20 ml saline flush at the same rate. A first scan is performed at 1 or 2 minutes after the administration of the contrast agent, depending on the presence of a clinical scan during the first-pass of contrast agent. The same scan is then repeated every minute until 10 minutes post injection, resulting in a total of 9 to 10 ELGE data sets. Afterwards, the standard 2D multi-slice LGE imaging is performed as frequently as possible (e.g., from 10 through 20 min after the contrast injection). The subject may be asked to hold the subject's breath at the start of each scan, which can be repeated as frequently as possible (e.g., every 30 sec or 1 min) after contrast injection.

### Example 2: Image Reconstruction and Analysis

Three-dimensional ELGE images are reconstructed from the two-fold under-sampled k-space data using iterative Self-consistent Parallel Imaging Reconstruction (SPIRiT). While conventional methods such as GRAPPA may be used for the correlation among multiple coils (e.g., calibration consistency) from acquired to missed k-space samples only, SPIRiT can apply it to entire k-space samples. In this way, SPIRiT maximally utilizes the calibration consistency, and improves reconstruction accuracy. Moreover, due to its generalized formulism of un-aliasing problem as a linear system, SPIRiT can be easily employed for non-Cartesian k-space trajectories. The fully sampled inner k-space data are used for coil calibration, and unacquired outer k-space is estimated using the SPIRiT reconstruction.

Since the time-resolved ELGE data are obtained during different breath-holds, image registration may be necessary for accurate temporal analysis. A region of interest (ROI) was manually specified to isolate the heart of the subject only. Based on the signal intensities within the ROI, 3D translations were iteratively found that produced the largest correlation between two data sets to be registered. Due to signal changes in blood pools and the myocardium over time, mutual information is used as a correlation measure, which can calculate a degree of similarity based on image contrasts rather than image intensities.

The registered time series of ELGE images are displayed by conventional grey scale and color scale for visual assessment. On datasets with MI, ROIs of 3.8 mm×3.8 mm square are manually specified within and outside the scar region. Time intensity curves are generated from the ROIs for the assessment of contrast uptake and wash-out.

### Example 3: Results

All subjects successfully underwent ELGE. FIG. 15 shows representative 3D ELGE images taken at 2 minutes after contrast agent administration from (a) a subject with myocardial infraction (MI) and (b) a subject without MI. The aliasing artifact from under-sampled k-space data is well suppressed due to successful SPIRiT parallel imaging reconstruction. FIG. 15A shows hypo-enhancement in the scar region due to lower perfusion of contrast agent whereas FIG. 15B exhibits homogeneous intensities over entire myocardium.

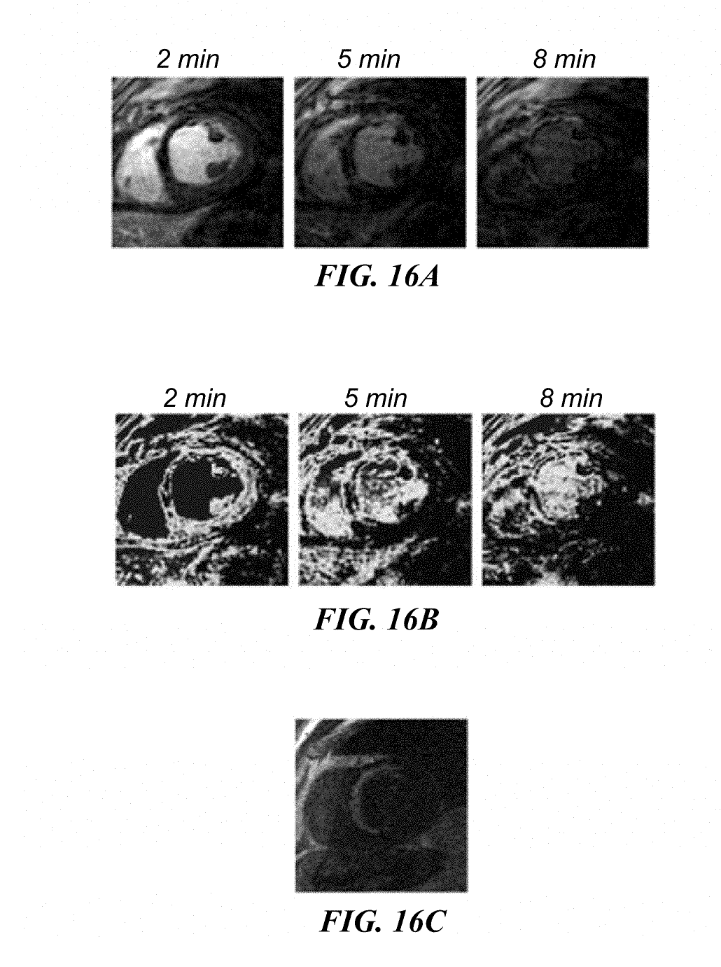

In an MI subject, signal intensity in the scar region is seen to gradually increase over time. However, it is observed that the level and rate of enhancement varies depending on spatial position and post-injection time. For example, as shown in FIGS. 16A and 16B, the relative spatial inhomogeneity of scar enhancement on anteroseptal wall differs between 5 minutes (“min”) and 8 min post-injection times. This temporal variation information is absent in the conventional 2D LGE image that is acquired at ˜15 min post injection. FIG. 16C is a two-dimensional (2D) image from a commercial LGE sequence at the same slice location. The signal intensity in the region of infarcted myocardium increases over time whereas the intensity in the region of normal myocardium decreases over time. Signal enhancement in the scar region is heterogeneous both spatially and temporally.

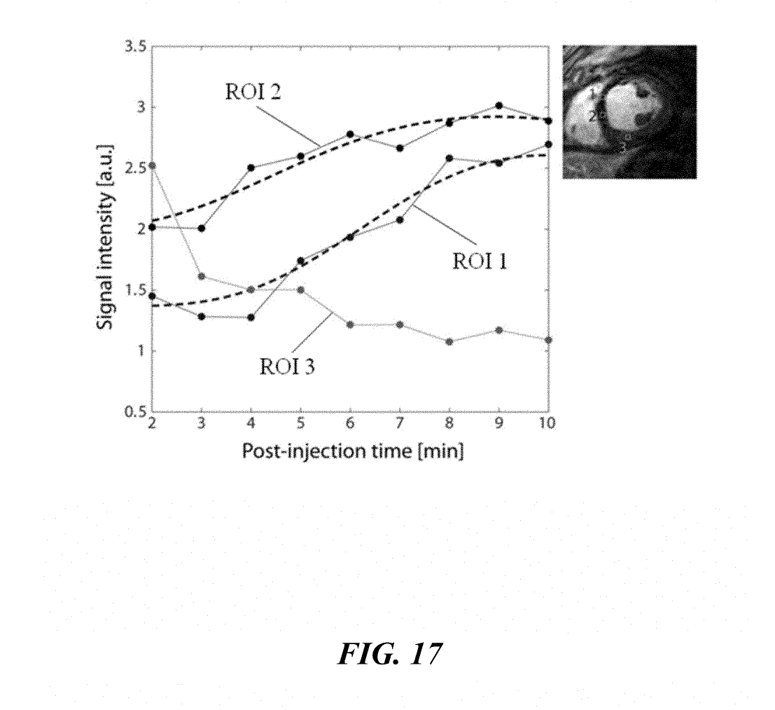

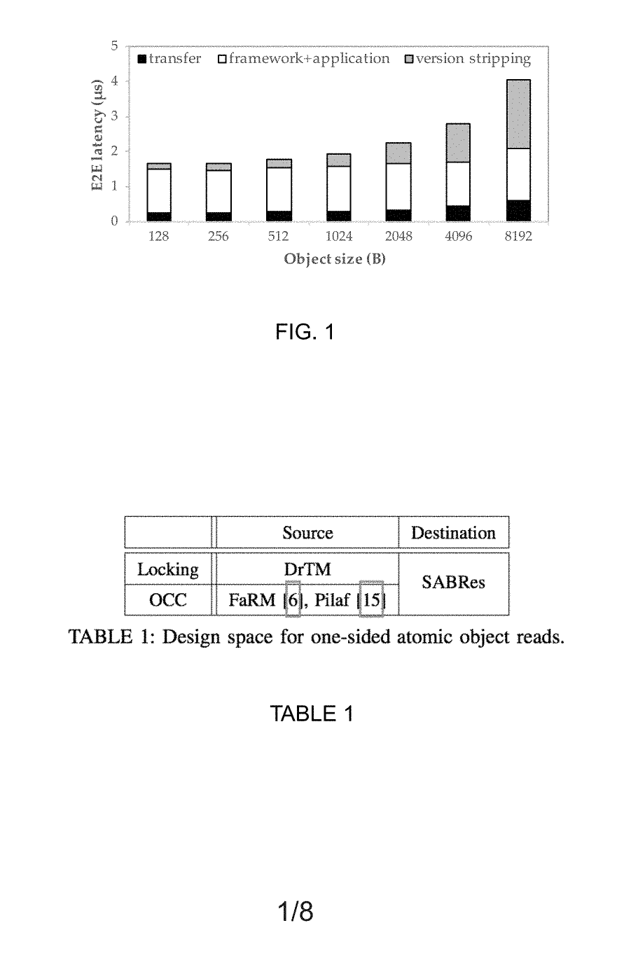

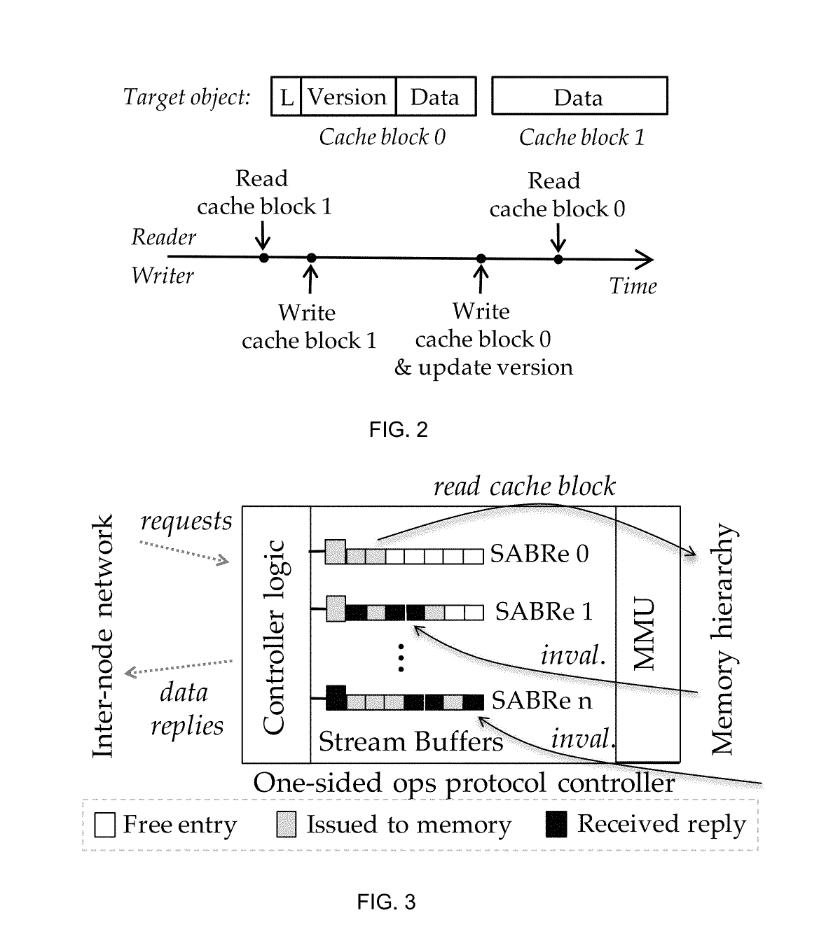

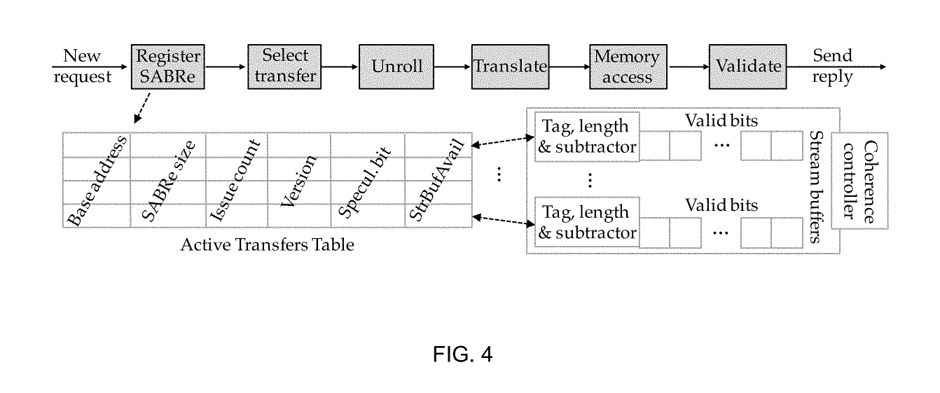

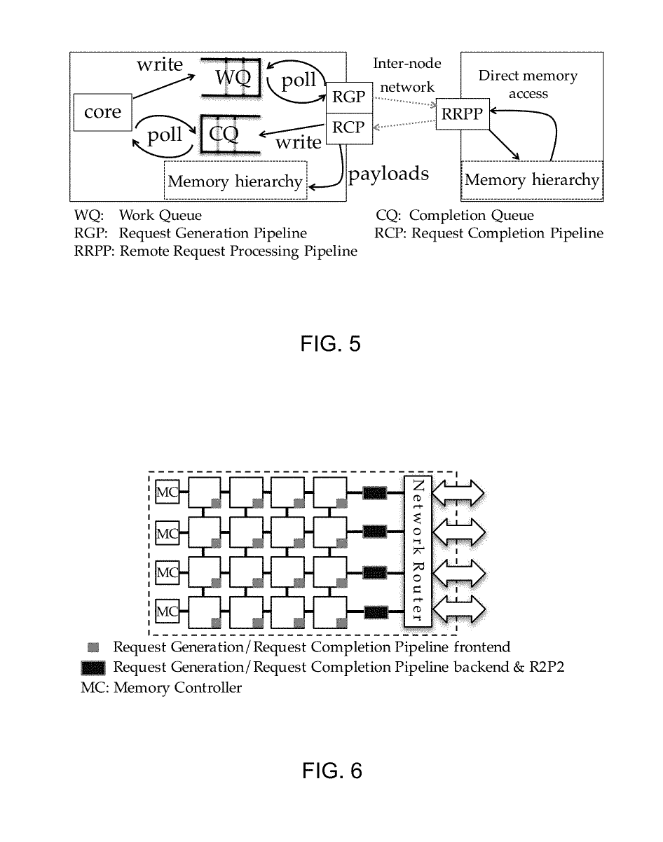

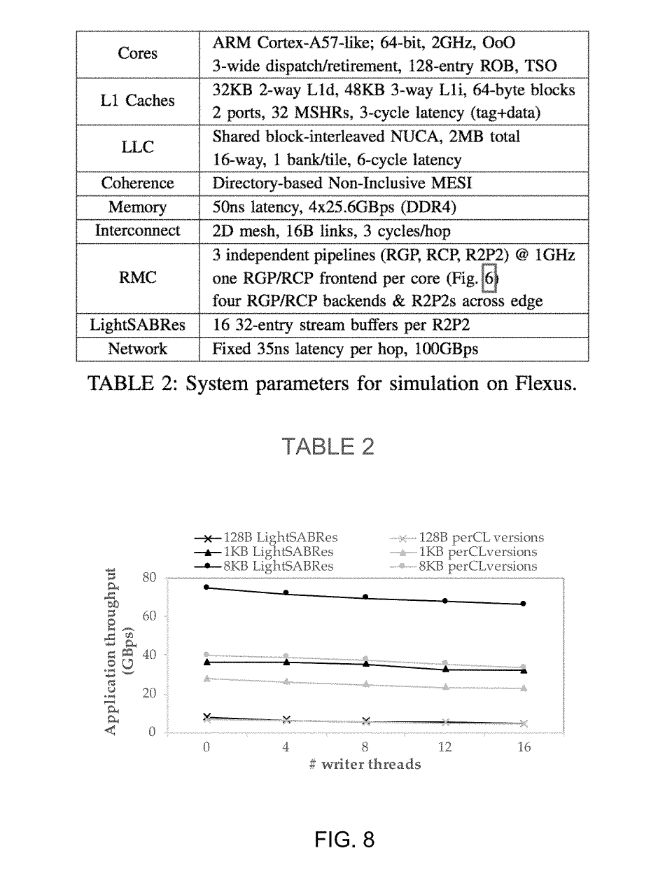

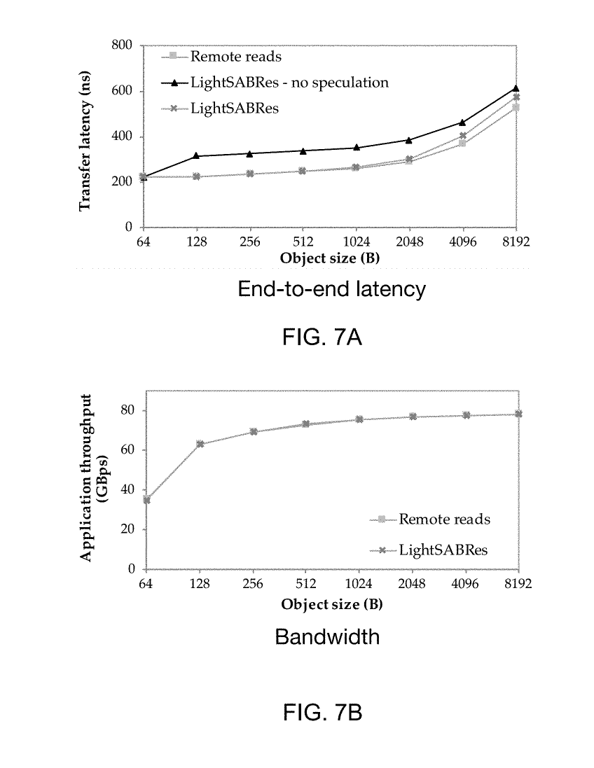

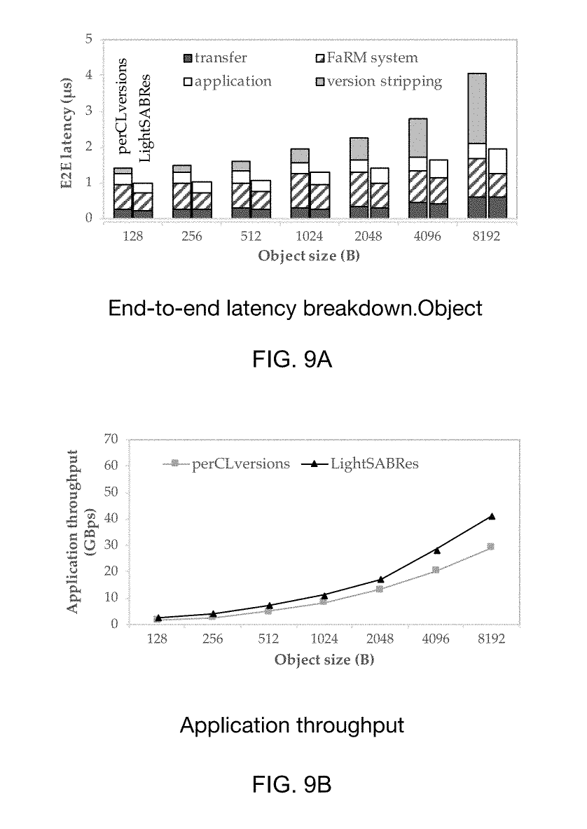

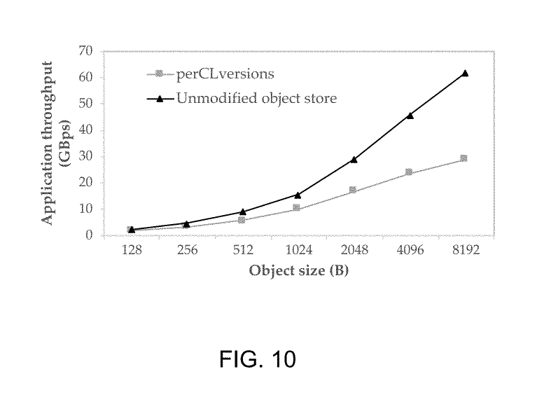

The spatial and temporal heterogeneity of ELGE phenomenon can be demonstrated by time-intensity curves of user-defined regions of interest (ROI). Examples of time-intensity curves are shown in FIG. 17 (solid lines). In FIG. 17, the y-axis corresponds to signal intensity and the x-axis corresponds to post-injection time. The signal intensities of both ROI 1 and 2 within scar region tend to increase globally over time, but at different rates. Specifically, the intensity of ROI 1 is lower at early enhancement and starts to increase slightly later in time than the intensity of ROI 2. The dashed line curves in FIG. 17 show fittings of the time curves to gamma-variate model written as At^{α} e^{-t/β18}. The estimated shape parameter α and scale parameter β are 1 e⁻⁴/7.02 for ROI 1, and 9.4 e⁻³/3.85 for ROI 2.

The parameters can help differentiate the kinetics of contrast washout in different myocardial regions. In FIG. 17, ROI3 represents healthy region and shows a steady decrease in signal intensity. Both ROIs 1 and 2 represent infarcted regions and show enhancement at later phases in time. ROIs 1 and 2 show nearly the same level enhancement at 10 minutes (the time for conventional late gadolinium enhancement MRI), but quite different kinetics during the 1 minute to 9 minute time interval, which may indicate a clinically meaningful difference in the level of infarction. In some situations, intensity versus time curves (see, e.g., FIG. 17) can be calculated by computing (i) the time until peak enhancement and (ii) the slope of a linear fit of the increasing portion of a curve.

With continued reference to FIG. 17, the first two ROIs are placed in the region of infarction, and the third ROI is in a normal remote region. The signal intensities from the first two ROIs gradually increase, but at different rates over time. The signal intensity from ROI 3 decreases over time consistent with normal wash-out of contrast agent.

Methods and systems of the disclosure may be combined with or modified by other methods and systems, such as those described in U.S. Pat. Nos. 5,512,825, 6,020,739, 6,198,282, 7,301,341, 5,465,361, 7,102,349, and 7,053,614; PCT Patent Publication No. WO/2004/042656; and Kim R J, Fieno D S, Parrish T B, Harris K, Chen E L, Simonetti O, Bundy J, Finn J P, Klocke F J, Judd R M, Relationship of mri delayed contrast enhancement to irreversible injury, infarct age, and contractile function, Circ. 1999, 100:1992-2002; Simonetti O P, Kim R J, Fieno D S, Hillenbrand H B, Wu E, Bundy J M, Finn J P, Judd R M, An improved mr imaging technique for the visualization of myocardial infarction, Radiology, 2001, 218:215-223; Hunold P, Schlosser T, Vogt F M, Eggebresht H, Schmermund A, Bruder O, Schuler W O, Barkhausen J, Myocardial late enhancement in contrast-enhanced cardiac mri: Distinction between infarction scar and non-infarction-related disease, Am J Roentgenol, 2005, 184:1420-1426; Gottlieb I, Macedo R, Bluemke D A, Lima J A, Magnetic resonance imaging in the evaluation of non-ischemic cardiomyopathies: Current applications and future perspectives, Heart Fail Rev, 2006, 11:313-323; Syed I S, Glockner J F, Feng D A, P. A., Martinez M W, Edwards W D, Gertz M A, Dispenzieri A, Oh J K, Bellavia D, Tajik A J, Grogan M, Role of cardiac magnetic resonance imaging in the detection of cardiac amyloidosis, JACC Cardiovasc Imaging, 2010, 3:155-164; Mahrholdt H, Wagner A, Judd R M, Sechtem U, Kim R J, Delayed enhancement cardiovascular magnetic resonance assessment of non-ischaemic cardiomyopathies, Eur Heart J, 2005, 26:1461-1474; Yan A T, Shayne A J, Brown K A, Gupta S N, Chan C W, Luu T M, Di Carli M F, Reynolds H G, Stevenson W G, Kwong R Y, Characterization of the peri-infarct zone by contrast-enhanced cardiac magnetic resonance imaging is a powerful predictor of post-myocardil infarction mortality, Circ. 2006, 114:32-39; Heidary S, Patel H, Chung J, Yokota H, Gupta S N, Bennett M V, Katikireddy C, Nguyen P, Pauly J M, Terashima M, McConnell M V, Yang P C, Quantitative tissue characterization of infarct core and border zone in patients with ischemic cardiomyopathy by magnetic resonance is associated with future cardiovascular events, J Am Coll Cardiol, 2010, 55:2762-2768; Schmidt A, Azevedo C F, Cheng A, Gupta S N, Bluemke D A, Foo T K, Gerstenblith G, Weiss R G, Marbán E, Tomaselli G F, Lima J A, Wu K C, Infarct tissue heterogeneity by magnetic resonance imaging identifies enhanced cardiac arrhythmia susceptibility in patients with left ventricular dysfunction, Circ. 2007, 115:2006-2014; Kim R J, Shah D J, Judd R M, How we perform delayed enhancement imaging, J Cardiovasc Magn Reson, 2003, 5:505-514; Vogel-Claussen J, Rochitte C E, Wu K C, Kamel I R, Foo T K, Lima J A, Bluemke D A, Delayed enhancement mr imaging: Utility in myocardial assessment, Radiographics, 2006, 26:795-810; Warntj es M J, Kihlberg J, Engvall J, Rapid t1 quantification based on 3d phase sensitive inversion recovery, BMC Med Imaging, 2010, 10:19; Foo T K, Stanley D W, Castillo E, Rochitte C E, Wang Y, Lima J A, Bluemke D A, Wu K C, Myocardial viability: Breath-hold 3d mr imaging of delayed hyperenhancement with variable sampling in time, Radiology, 2004, 230:845-851; Pablo Irarrazabal, Craig H. Meyer, Dwight G. Nishimura, Macovski A, Inhomogeneity correction using an estimated linear field map, Magn Reson Med, 1996, 35:278-282; Lustig M, Pauly J M, Spirit: Iterative self-consistent parallel imaging reconstruction from arbitrary k-space, Magn Reson Med, 2010, 64:457-471; Griswold M A, Jakob P M, Heidemann R M, Nittka M, Jellus V, Wang J, Kiefer B, Haase A, Generalized autocalibrating partially parallel acquisitions (grappa), Magn Reson Med, 2002, 47:1202-1210; Pluim J P W, Maintz J B A, Viergever M A, Mutual-information-based registration of medical images: A survey, IEEE Trans Med Imaging, 2003, 22:986-1004; Mischi M, den Boer J A, Korsten H H, On the physical and stochastic representation of an indicator dilution curve as a gamma variate, Physiol Meas, 20080, 29:281-294; Jerosch-Herold M, Wilke N, Stillman A E, Magnetic resonance quantification of the myocardial perfusion reserve with a fermi function model for constrained deconvolution, Med Phys, 1998, 25:73-84; and Albert M S, Huang W, Lee J-H, Patlak C S, Springer C S, Susceptibility changes following bolus injections, Magn Reson Med, 1993, 29:700-708, each of which is entirely incorporated herein by reference.

It should be understood from the foregoing that, while particular implementations have been illustrated and described, various modifications can be made thereto and are contemplated herein. It is also not intended that the invention be limited by the specific examples provided within the specification. While the invention has been described with reference to the aforementioned specification, the descriptions and illustrations of the preferable embodiments herein are not meant to be construed in a limiting sense. Furthermore, it shall be understood that all aspects of the invention are not limited to the specific depictions, configurations or relative proportions set forth herein which depend upon a variety of conditions and variables. Various modifications in form and detail of the embodiments of the invention will be apparent to a person skilled in the art. It is therefore contemplated that the invention shall also cover any such modifications, variations and equivalents. It is intended that the following claims define the scope of the invention and that methods and structures within the scope of these claims and their equivalents be covered thereby.

What is claimed is:

1. A method for generating magnetic field gradients for use in magnetic resonance imaging (Mill), the method comprising:
a) transforming, with the aid of a computer processor, a set of gradient parameters from a physical gradient space into a transformed space;
b) calculating, with the aid of a computer processor, a set of separable gradient waveforms that satisfy a set of gradient rate-of-change constraints in said transformed space;
c) repeating steps (a)-(b) until the gradient waveforms in said set of separable gradient waveforms are of substantially the same time length; and
d) transforming, with the aid of a computer processor, a resulting gradient set of waveforms of substantially the same time length back into said physical gradient space.

2. The method of claim 1, wherein said set of gradient parameters contains parameters that include a gradient start magnitude, gradient end magnitude, gradient amplitude, gradient first moment, and higher-order gradient moments.

3. The method of claim 2, wherein at least two of said parameters of said set of gradient parameters are used.

4. The method of claim 1, wherein step (c) is nonlinear.

5. The method of claim 1, wherein the set of rate-of-change constraints comprises at least one of a physical hardware constraint and a regulatory safety constraint.

6. The method of claim 1, wherein said transformed space is a result of one or more of a rotative transformation, a proportional transformation, or a magnitude transformation.

7. A method for acquiring a volumetric scan from a heart of a subject, the method comprising:
(a) administering a precursor of a contrast agent to said subject, wherein the precursor of the contrast agent yields the contrast agent in the heart of the subject, and wherein the contrast agent is retained less in healthy myocardial tissue of the heart than in abnormal myocardial tissue of the heart;
(b) applying an inversion radiofrequency (RF) pulse to the heart with the aid of an RF source of a magnetic resonance imaging (MRI) system, wherein said inversion RF pulse is applied between successive heartbeats of a cardiac cycle of said subject and within a single breath hold of said subject, and wherein said inversion RF pulse reduces or eliminates magnetic resonance (MR) signals from the healthy myocardial tissue of the heart where the contrast agent is less retained;
(c) detecting magnetic resonance (MR) signals from the heart with the aid of a detector coil of said MRI system, wherein said MR signals are detected subsequent to a time delay upon applying said inversion RF pulse, and wherein said MR signals are detected between said successive heartbeats within said single breath hold;
(d) storing said MR signals in a memory location as non-Cartesian data in k-space;
(e) capturing an image of a slice of the heart, wherein the slice corresponds to an incomplete data set insufficient to generate a complete image of the heart;
(f) repeating (b)-(e) within said single breath hold of said subject to capture a plurality of images of slices of the heart, wherein the plurality of the images of the slices correspond to a complete data set sufficient to generate the complete image of the heart; and
(g) iteratively processing, with the aid of a computer processor, said non-Cartesian data corresponding to said plurality of images of slices of the heart, in a self-consistent and parallel manner, to reconstruct a three-dimensional volumetric scan, the three-dimensional volumetric scan comprising the complete image of the heart and showing enhanced contrast between the healthy and abnormal myocardial tissue.

8. The method of claim 7, wherein said non-Cartesian data comprises a stack of spirals in k-space.

9. The method of claim 7, further comprising repeating (b)-(d) at least ten times within said single breath hold of said subject.

10. The method of claim 7, further comprising repeating (b)-(d) at least fifteen times within said single breath hold of said subject.

11. The method of claim 7, wherein said non-Cartesian data comprises one or more spirals in k-space.

12. The method of claim 11, wherein an inner part of a given one of said one or more spirals is fully sampled and an outer part of said given spiral is under-sampled, and wherein in (g), said outer part of said three-dimensional volumetric scan is reconstructed in said self-consistent and parallel manner.

13. The method of claim 7, wherein said contrast agent comprises hyperpolarized chemical species, paramagnetic agent, or ferromagnetic agent.

14. The method of claim 7, further comprising diagnosing said subject for said disease or adverse health condition based upon an assessment of said three-dimensional volumetric scan of the heart.

15. The method of claim 14, further comprising generating a plurality of three-dimensional volumetric scans of the heart, wherein the plurality of scans of the heart show wash-out of the contrast agent over time from one or more of the healthy or abnormal myocardial tissues over time.

16. The method of claim 16, further comprising determining intensities of a given portion of said plurality of scans; generating a trajectory of said intensities with time based on the determined intensities; and, wherein diagnosing said subject for said disease or adverse health condition based on the assessment comprises generating the assessment based on the generated trajectory, the trajectory indicating one or more of a rate of wash-out of the contrast agent from healthy myocardial tissue or a rate of wash-out of the contrast agent from abnormal myocardial tissue.

17. The method of claim 7, wherein said three-dimensional volumetric scan is generated using generalized auto-calibrating partially parallel acquisition.

18. The method of claim 7, wherein, during a single cardiac cycle, said non-Cartesian data corresponds to at most 15% of the data set for generating said three-dimensional volumetric scan of the heart.

19. The method of claim 7, further comprising, between steps (b) and (c), supplying a fat saturation RF pulse to the heart.

20. The method of claim 7, further comprising, in steps (c), detecting said MR signals during mid-diastole.

21. The method of claim 7, wherein said MR signals are detected from multiple regions of interest in the heart.

22. The method of claim 7, wherein steps (b)-(d) are repeated at least one time within said single breath hold of said subject to generate a data set corresponding to a first post-injection time point.

23. The method of claim 22, further comprising repeating steps (b)-(f) to generate a plurality of data sets, wherein each repetition of steps (b)-(f) is performed within a separate breath-hold of said subject.

24. The method of claim 23, wherein each data set corresponds to a separate time point subsequent to the administering of the precursor of the contrast agent to said subject.

25. The method of claim 7, wherein said single breath hold comprises 30 heart beats or less.

26. The method of claim 7, wherein said single breath hold comprises 15 heart beats or less.

27. The method of claim 7, wherein step (f) comprises acquiring at least five readouts within said single breath hold.

28. The method of claim 7, wherein step (f) comprises acquiring at least ten readouts within said single breath hold.

29. The method of claim 7, wherein step (f) comprises acquiring at least fifteen readouts within said single breath hold.

30. The method of claim 7, wherein in (g), said non-Cartesian data is iteratively processed in a self-consistent and parallel manner at an acceleration rate greater than 1.

31. The method of claim 7, wherein in (g), said non-Cartesian data in k-space is reconstructed using coil sensitivity encoding through all of said non-Cartesian data in k-space.

32. A method for characterizing myocardial tissue viability to determine a disease state of a heart of a subject, the method comprising:
(a) acquiring a plurality of two-dimensional (2D) magnetic resonance (MR) image sets of the heart over a plurality of breath-hold periods of the subject, each 2D MR image set being acquired from the heart during an individual breath-hold period of the plurality of breath-hold periods;
(b) generating a plurality of three-dimensional (3D) MR images of the heart, each 3D image being generated from an individual 2D MR image set;
(c) generating a time series of 3D MR images from the plurality of 3D MR images, the time series comprising MR intensities of a plurality of regions of the heart over the plurality of breath-hold periods;
(d) determining washout rates of an MR contrast agent from the plurality of regions of the heart based on the MR intensities of the plurality of regions of the heart over the plurality of breath-hold periods; and
(e) assessing viabilities of the plurality of regions of the heart based on their determined washout rates,
wherein a lower washout rate indicates a lesser decrease of MR intensity over the plurality of breath-hold periods and injured tissue, and
wherein a higher washout rate indicates a higher decrease of MR intensity over the plurality of breath-hold periods and normal tissue.

33. The method of claim 32, wherein the MR contrast agent comprises hyperpolarized chemical species, paramagnetic agent, or ferromagnetic agent.

34. The method of claim 32, wherein the MR contrast agent comprises gadolinium.

35. The method of claim 32, wherein acquiring the plurality of two-dimensional (2D) MR image sets of the heart over the plurality of breath-hold periods of the subject comprises:
(a) applying an inversion radiofrequency (RF) pulse to the heart between successive heartbeats of a cardiac cycle of the subject and within an individual breath-hold period of the subject,
(b) detecting at least one MR signal in response to the inversion RF pulse,
(c) generating a single 2D MR image from the detected at least one MR signal,
(d) repeating steps (a) to (c) to generate an individual 2D MR image set over an individual breath-hold period, and
(e) repeating steps (a) to (d) to generate a plurality of 2D MR image sets over the plurality of breath-hold periods.

36. The method of claim 32, wherein the plurality of 2D MR images sets are acquired with the aid of a detector coil of said MRI system.

37. The method of claim 32, wherein the plurality of 3D MR images of the heart is generated with the aid of a computer processor.

38. The method of claim 32, wherein the time series of 3D MR images is generated with the aid of a computer processor.

39. The method of claim 32, wherein the washout rate of the MR contrast agent is determined with the aid of a computer processor.

40. The method of claim 32, wherein the viabilities of the plurality of regions of the heart is assessed with the aid of a computer processor.
